(19) United States
(12) Patent Application Publication
(10) Pub. No.: US 2025/0359321 A1
(43) Pub. Date: Nov. 20, 2025

(54) ISOLATED SHARED CONTACT FOR STACKED FIELD EFFECT TRANSISTOR

(71) Applicant: INTERNATIONAL BUSINESS MACHINES CORPORATION, ARMONK, NY (US)

(72) Inventors: Min Gyu Sung, Latham, NY (US); Tao Li, Slingerlands, NY (US); Ruilong Xie, Niskayuna, NY (US); Albert Manhee Chu, Nashua, NH (US)

(21) Appl. No.: 18/668,373

(22) Filed: May 20, 2024

(51) Int. Cl. H01L 27/092; H01L 21/285; H01L 21/822; H01L 21/8238; H01L 23/528; H01L 29/06; H01L 29/417; H01L 29/423; H01L 29/45; H01L 29/66; H01L 29/775

(52) U.S. Cl. CPC H10D 84/856; H01L 21/28518; H01L 23/5286; H10D 30/014; H10D 30/43; H10D 30/6729; H10D 30/6735; H10D 62/121; H10D 64/62; H10D 84/017; H10D 84/0186; H10D 84/038; H10D 88/01

(57) ABSTRACT

According to the embodiment of the present invention, a semiconductor device comprises a first nanodevice including a plurality of first upper transistors and a plurality of first lower transistors. The first nanodevice includes a first upper source/drain and a first lower source/drain. A shared source/drain contact extends through the first upper source/drain and the first lower source/drain. An isolation interlayer dielectric (ILD) is in direct contact with at least one surface of the shared source/drain contact.

### BACKGROUND

The present invention relates generally to the field of microelectronics, and more particularly to a semiconductor device structure, and a method for forming a semiconductor device.

A nanosheet (NS) is the lead device architecture in continuing CMOS scaling. However, nanosheet technology has shown issues when scaling down such that as the devices become smaller and closer together, they are interfering with each other. Furthermore, as the devices become smaller and closer together, forming the connections to a backside power network is becoming more difficult.

### SUMMARY

According to the embodiment of the present invention, a semiconductor device comprises a first nanodevice including a plurality of first upper transistors and a plurality of first lower transistors. The first nanodevice includes a first upper source/drain and a first lower source/drain. A shared source/drain contact extends through the first upper source/drain and the first lower source/drain. An isolation interlayer dielectric (ILD) is in direct contact with at least one surface of the shared source/drain contact.

According to the embodiment of the present invention, a semiconductor device comprises a first nanodevice including a plurality of first upper transistors and a plurality of first lower transistors. The first nanodevice includes a first upper source/drain, a second upper source/drain, a first lower source/drain, and a second lower source/drain. A shared source/drain contact extends through the first upper source/drain and the first lower source/drain. A first independent source/drain contact extends upwards through the second upper source/drain and a first independent backside source/drain contact extends downwards through the second lower source/drain. An isolation ILD is in direct contact with at least one surface of the shared source/drain contact.

According to the embodiment of the present invention, a semiconductor device comprises a first nanodevice including a plurality of first upper transistors and a plurality of first lower transistors and a second nanodevice including a plurality of second upper transistors and a plurality of second lower transistors. The first nanodevice includes a first upper source/drain, a second upper source/drain, a first lower source/drain, and a second lower source/drain. The second nanodevice is located adjacent to and parallel to the first nanodevice. The second nanodevice includes a third upper source/drain and a third lower source/drain. A shared source/drain contact extends through the first upper source/drain and the first lower source/drain. A first independent source/drain contact extends upwards through the second upper source/drain, a second independent source/drain contact extends upwards through the third upper source/drain, a first independent backside source/drain contact extends downwards through the second lower source/drain, and a second independent backside source/drain contact extends downwards through the third lower source/drain. An isolation ILD is in direct contact with at least one surface of the shared source/drain contact.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates a top-down view of a plurality of nanodevices, in accordance with the embodiment of the present invention.

FIGS. 2-4 illustrate cross sections X, Y₁, and Y₂, respectively, of the plurality of nanodevices after interlayer dielectric (ILD) deposition, nanosheet formation, shallow trench isolation (STI) region formation, gate formation, gate spacer and inner spacer formation, middle dielectric isolation (MDI) layer formation, source/drain formation, etch stop layer formation, sacrificial placeholder formation, protective liner formation, gate cut dielectric pillar formation, and CMP, in accordance with the embodiment of the present invention.

FIGS. 5-7 illustrate cross sections X, Y₁, and Y₂, respectively, of the plurality of nanodevices after the formation of a first trench, a second trench, and a third trench, in accordance with the embodiment of the present invention.

FIGS. 8-10 illustrate cross sections X, Y₁, and Y₂, respectively, of the plurality of nanodevices after the formation of a first source/drain contact, a first independent source drain contact, and a second independent source/drain contact, a plurality of gate contacts, and frontside silicide liners, in accordance with the embodiment of the present invention.

FIGS. 11-13 illustrate cross sections X, Y₁, and Y₂, respectively, of the plurality of nanodevices after the formation of a lithography mask layer and a fourth trench, in accordance with the embodiment of the present invention.

FIGS. 14-16 illustrate cross sections X, Y₁, and Y₂, respectively, of the plurality of nanodevices after the formation of an isolation ILD and CMP, in accordance with the embodiment of the present invention.

FIGS. 17-19 illustrate cross sections X, Y₁, and Y₂, respectively, of the plurality of nanodevices after the formation of a back-end-of-line (BEOL) layer, a bonding oxide layer, and bonding to a carrier wafer, in accordance with the embodiment of the present invention.

FIGS. 20-22 illustrate cross sections X, Y₁, and Y₂, respectively, of the plurality of nanodevices after the carrier wafer is flipped and the substrate is removed, in accordance with the embodiment of the present invention.

FIGS. 23-25 illustrate cross sections X, Y₁, and Y₂, respectively, of the plurality of nanodevices after the removal of the etch stop layer and the underlying substrate layer, backside ILD (BILD) layer deposition, and CMP, in accordance with the embodiment of the present invention.

FIGS. 26-28 illustrate cross sections X, Y₁, and Y₂, respectively, of the plurality of nanodevices after the removal of the sacrificial placeholder, in accordance with the embodiment of the present invention.

FIGS. 29-31 illustrate cross sections X, Y₁, and Y₂, respectively, of the plurality of nanodevices after the formation of a fifth trench, a sixth trench, and a seventh trench, in accordance with the embodiment of the present invention.

FIGS. 32-34 illustrate cross sections X, Y₁, and Y₂, respectively, of the plurality of nanodevices after the formation of a second source/drain contact, a second independent backside source/drain contact, a third independent backside source/drain contact, and a backside silicide liner, in accordance with the embodiment of the present invention.

FIGS. 35-37 illustrate cross sections X, Y₁, and Y₂, respectively, of the plurality of nanodevices after the formation of a backside interconnect in accordance with the embodiment of the present invention.

FIGS. 38-40 illustrate cross sections X, Y₁, and Y₂, respectively, of the plurality of nanodevices after ILD deposition, nanosheet formation, STI region formation, gate formation, gate spacer and inner spacer formation, MDI layer formation, source/drain formation, etch stop layer formation, sacrificial placeholder formation, protective liner formation, gate cut dielectric pillar formation, and CMP, in accordance with the embodiment of the present invention.

FIGS. 41-43 illustrate cross sections X, Y₁, and Y₂, respectively, of the plurality of nanodevices after the formation of the first trench, the second trench, and the third trench, in accordance with the embodiment of the present invention.

FIGS. 44-46 illustrate cross sections X, Y₁, and Y₂, respectively, of the plurality of nanodevices after the formation of a first source/drain contact, a first independent source drain contact, and a second independent source/drain contact, a plurality of gate contacts, and frontside silicide liners, in accordance with the embodiment of the present invention.

FIGS. 47-49 illustrate cross sections X, Y₁, and Y₂, respectively, of the plurality of nanodevices after the formation of the BEOL layer, the bonding oxide layer, and bonding to the carrier wafer, in accordance with the embodiment of the present invention.

FIGS. 50-52 illustrate cross sections X, Y₁, and Y₂, respectively, of the plurality of nanodevices after the carrier wafer is flipped and the substrate is removed, in accordance with the embodiment of the present invention.

FIGS. 53-55 illustrate cross sections X, Y₁, and Y₂, respectively, of the plurality of nanodevices after the removal of the etch stop layer and the underlying substrate layer, BILD layer deposition, and CMP, in accordance with the embodiment of the present invention.

FIGS. 56-58 illustrate cross sections X, Y₁, and Y₂, respectively, of the plurality of nanodevices after the removal of the sacrificial placeholder, in accordance with the embodiment of the present invention.

FIGS. 59-61 illustrate cross sections X, Y₁, and Y₂, respectively, of the plurality of nanodevices after the formation of the fifth trench, the sixth trench, and the seventh trench, in accordance with the embodiment of the present invention.

FIGS. 62-64 illustrate cross sections X, Y₁, and Y₂, respectively, of the plurality of nanodevices after the formation of the second source/drain contact, the second independent backside source/drain contact, the third independent backside source/drain contact, and the backside silicide liner, in accordance with the embodiment of the present invention.

FIGS. 65-67 illustrate cross sections X, Y₁, and Y₂, respectively, of the plurality of nanodevices after the formation of a second lithography mask layer and an eighth trench, in accordance with the embodiment of the present invention.

FIGS. 68-70 illustrate cross sections X, Y₁, and Y₂, respectively, of the plurality of nanodevices after the formation of the isolation ILD, an isolation STI material, and CMP, in accordance with the embodiment of the present invention.

FIGS. 71-73 illustrate cross sections X, Y₁, and Y₂, respectively, of the plurality of nanodevices after the formation of the backside interconnect, in accordance with the embodiment of the present invention.

FIGS. 74-76 illustrate cross sections X, Y₁, and Y₂, respectively, of the plurality of nanodevices after ILD deposition and additional ILD deposition, nanosheet formation, STI region formation, gate formation, gate spacer and inner spacer formation, MDI layer formation, source/drain formation, source/drain contact formation, gate contact formation, protective liner formation, gate cut dielectric pillar formation, first frontside silicide liner formation, backside silicide liner formation, BEOL layer formation, bonding oxide layer formation, carrier wafer bonding, BILD layer formation, isolation ILD formation, STI isolation material formation, and backside interconnect formation, in accordance with the embodiment of the present invention.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

References in the specification to “one embodiment,” “an embodiment,” “an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art to affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “formed on,” or “formed atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be a direct or indirect positional relationship. As an example of an indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both an indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of +8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes which are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout.

Clause 1. A semiconductor device comprises a first nanodevice including a plurality of first upper transistors and a plurality of first lower transistors, where the first nanodevice includes a first upper source/drain and a first lower source/drain. A shared source/drain contact extends through the first upper source/drain and the first lower source/drain. An isolation interlayer dielectric (ILD) is in direct contact with at least one surface of the shared source/drain contact. This embodiment has the advantage of allowing for a larger critical dimension of the shared source/drain contact, thereby reducing the resistance of the shared source/drain contact.

Clause 2. The semiconductor device of clause 1, where the isolation ILD may include a frontside isolation ILD in direct contact with a frontside surface of the shared source/drain contact. This embodiment has the advantage of optimizing the shared source/drain contact from a frontside and a backside of the semiconductor device.

Clause 3. The semiconductor device of any of the preceding clauses, where the semiconductor device may further comprise a back-end-of-line (BEOL) layer in direct contact with a frontside surface of the frontside isolation ILD. This embodiment has the advantage of optimizing the shared source/drain contact from the frontside and the backside of the semiconductor device.

Clause 4. The semiconductor device of any of the preceding clauses, where the isolation ILD may include a backside isolation ILD in direct contact with a backside surface of the shared source/drain contact. This embodiment has the advantage of optimizing the shared source/drain contact from the frontside and the backside of the semiconductor device.

Clause 5. The semiconductor device of any of the preceding clauses, where the semiconductor device may further comprise a backside interconnect in direct contact with a backside surface of the backside isolation ILD. This embodiment has the advantage of optimizing the shared source/drain contact from the frontside and the backside of the semiconductor device.

Clause 6. The semiconductor device of any of the preceding clauses, where the isolation ILD may include a frontside isolation ILD in direct contact with a frontside surface of the shared source/drain contact and a backside isolation ILD in direct contact with a backside surface of the shared source/drain contact. This embodiment has the advantage of optimizing the shared source/drain contact from the frontside and the backside of the semiconductor device.

Clause 7. The semiconductor device of any of the preceding clauses, where the semiconductor device may further comprise a BEOL layer in direct contact with a frontside surface of the frontside isolation ILD. A backside interconnect may be in direct contact with a backside surface of the backside isolation ILD. This embodiment has the advantage of optimizing the shared source/drain contact from the frontside and the backside of the semiconductor device.

Clause 8. A semiconductor device comprises a first nanodevice including a plurality of first upper transistors and a plurality of first lower transistors, where the first nanodevice includes a first upper source/drain, a second upper source/drain, a first lower source/drain, and a second lower source/drain. A shared source/drain contact extends through the first upper source/drain and the first lower source/drain. A first independent source/drain contact extends upwards through the second upper source/drain and a first independent backside source/drain contact extends downwards through the second lower source/drain. An isolation interlayer dielectric (ILD) is in direct contact with at least one surface of the shared source/drain contact. This embodiment has the advantage of allowing for a larger critical dimension of the shared source/drain contact, thereby reducing the resistance of the shared source/drain contact.

Clause 9. The semiconductor device of any of the preceding clauses, where the isolation ILD may include a frontside isolation ILD in direct contact with a frontside surface of the shared source/drain contact. This embodiment has the advantage of optimizing the shared source/drain contact from the frontside and the backside of the semiconductor device.

Clause 10. The semiconductor device of any of the preceding clauses, where the semiconductor device may further comprise a BEOL layer in direct contact with a frontside surface of the frontside isolation ILD and a frontside surface of the first independent source/drain contact. This embodiment has the advantage of optimizing the shared source/drain contact from the frontside and the backside of the semiconductor device.

Clause 11. The semiconductor device of any of the preceding clauses, where the isolation ILD may include a backside isolation ILD in direct contact with a backside surface of the shared source/drain contact. This embodiment has the advantage of optimizing the shared source/drain contact from the frontside and the backside of the semiconductor device.

Clause 12. The semiconductor device of any of the preceding clauses, where the semiconductor device may further comprise a backside interconnect in direct contact with a backside surface of the backside isolation ILD and a backside surface of the first independent backside source/drain contact. This embodiment has the advantage of optimizing the shared source/drain contact from the frontside and the backside of the semiconductor device.

Clause 13. The semiconductor device of any of the preceding clauses, where the isolation ILD may include a frontside isolation ILD in direct contact with a frontside surface of the shared source/drain contact and a backside isolation ILD in direct contact with a backside surface of the shared source/drain contact. This embodiment has the advantage of optimizing the shared source/drain contact from the frontside and the backside of the semiconductor device.

Clause 14. The semiconductor device of any of the preceding clauses, where the semiconductor device may further comprise a BEOL layer in direct contact with a frontside surface of the frontside isolation ILD and a frontside surface of the first independent source/drain contact. A backside interconnect may be in direct contact with a backside surface of the backside isolation ILD and a backside surface of the first independent backside source/drain contact. This embodiment has the advantage of optimizing the shared source/drain contact from the frontside and the backside of the semiconductor device.

Clause 15. A semiconductor device comprises a first nanodevice including a plurality of first upper transistors and a plurality of first lower transistors and a second nanodevice including a plurality of second upper transistors and a plurality of second lower transistors. The first nanodevice includes a first upper source/drain, a second upper source/drain, a first lower source/drain, and a second lower source/drain. The second nanodevice is located adjacent to and parallel to the first nanodevice. The second nanodevice includes a third upper source/drain and a third lower source/drain. A shared source/drain contact extends through the first upper source/drain and the first lower source/drain. A first independent source/drain contact extends upwards through the second upper source/drain, a second independent source/drain contact extends upwards through the third upper source/drain, a first independent backside source/drain contact extends downwards through the second lower source/drain, and a second independent backside source/drain contact extends downwards through the third lower source/drain. An isolation ILD is in direct contact with at least one surface of the shared source/drain contact. This embodiment has the advantage of allowing for a larger critical dimension of the shared source/drain contact, thereby reducing the resistance of the shared source/drain contact.

Clause 16. The semiconductor device of any of the preceding clauses, where the isolation ILD may include a frontside isolation ILD in direct contact with a frontside surface of the shared source/drain contact. The semiconductor device may further comprise a BEOL layer in direct contact with a frontside surface of the frontside isolation ILD, a frontside surface of the first independent source/drain contact, and a frontside surface of the second independent source/drain contact. This embodiment has the advantage of optimizing the shared source/drain contact from the frontside and the backside of the semiconductor device.

Clause 17. The semiconductor device of any of the preceding clauses, where the isolation ILD may include a backside isolation ILD in direct contact with a backside surface of the shared source/drain contact. The semiconductor device may further comprise a backside interconnect in direct contact with a backside surface of the backside isolation ILD, a backside surface of the first independent backside source/drain contact, and a backside surface of the second independent backside source/drain contact. This embodiment has the advantage of optimizing the shared source/drain contact from the frontside and the backside of the semiconductor device.

Clause 18. The semiconductor device of any of the preceding clauses, where the isolation ILD may include a frontside isolation ILD in direct contact with a frontside surface of the shared source/drain contact and a backside isolation ILD in direct contact with a backside surface of the shared source/drain contact. The semiconductor device may further comprise a BEOL layer in direct contact with a frontside surface of the frontside isolation ILD, a frontside surface of the first independent source/drain contact, and a frontside surface of the second independent source/drain contact. A backside interconnect may be in direct contact with a backside surface of the backside isolation ILD, a backside surface of the first independent backside source/drain contact, and a backside surface of the second independent backside source/drain contact. This embodiment has the advantage of optimizing the shared source/drain contact from the frontside and the backside of the semiconductor device.

Clause 19. The semiconductor device of any of the preceding clauses, where the shared source/drain contact may extend a first height perpendicular to a y-axis, where the first independent source/drain contact and the first independent backside source/drain contact each extend a second height perpendicular to the y-axis, where the first height is greater than the second height. This embodiment has the advantage of optimizing the shared source/drain contact from the frontside and the backside of the semiconductor device.

Clause 20. The semiconductor device of any of the preceding clauses, where the semiconductor device may further comprise a frontside silicide liner located along a first portion of sidewalls of the shared source/drain contact where the shared source/drain contact passes through the first upper source/drain. A backside silicide liner may be located along a second portion of the sidewalls of the shared source/drain contact where the shared source/drain contact passes through the first lower source/drain, where the frontside silicide liner and the backside silicide liner may be comprised of a different material. This embodiment has the advantage of optimizing the shared source/drain contact from the frontside and the backside of the semiconductor device.

Currently in CMOS circuits, there is no sound solution for shared source/drain contact formation. By forming a deep independent source/drain contact in a stacked field effect transistor (FET) from a frontside of a nanodevice, a small critical dimension of a backside of the deep independent source/drain contact results in high resistance source/drain contact.

By forming a source/drain contact from a frontside of the nanodevice and another source/drain contact from a backside of the nanodevice that are connected to each other (e.g., a shared source/drain contact), a critical dimension of the shared source/drain contact may be larger than a critical dimension of the deep independent source/drain contact. The present invention does not require that all advantages need to be incorporated into every embodiment of the invention.

The present invention is directed to forming an isolated shared contact in a stacked FET. The isolated shared contact is formed through a multistage processing, where the first stage forms a first trench by etching a portion of an interlayer dielectric (ILD) and a first upper source/drain, a second trench by etching a portion of a second upper source/drain and the ILD, and a third trench by etching a portion of a third upper source/drain and the ILD. The second stage fills the first trench, the second trench, and the third trench with a conductive metal, forming a first source/drain contact, a first independent source/drain contact, and a second independent source/drain contact, respectively. The third stage forms a fourth trench by etching a portion of the first source/drain contact and the ILD. The fourth stage fills the fourth trench with a dielectric material to form a first isolation ILD above the first source/drain contact. The fifth stage forms a back-end-of-line (BEOL) above the first isolation ILD, the first independent source/drain contact, and the second independent source/drain contact. The sixth stage forms a fifth trench by removing a sacrificial placeholder, etching a portion of a backside interlayer dielectric (BILD) layer, and a second lower source/drain, a sixth trench by removing the sacrificial placeholder and etching a portion of a first lower source/drain, and a seventh trench by removing the sacrificial placeholder and etching a portion of a third lower source/drain. The seventh stage fills the fifth trench, the sixth trench, and the seventh trench with the conductive metal, forming a first independent backside source/drain contact, the backside source/drain contact, and a second independent backside source/drain contact, respectively. The eighth stage forms a backside interconnect above the backside source/drain contact, the first independent backside source/drain contact, the second independent backside source/drain contact, the BILD layer, and a shallow trench isolation (STI) region.

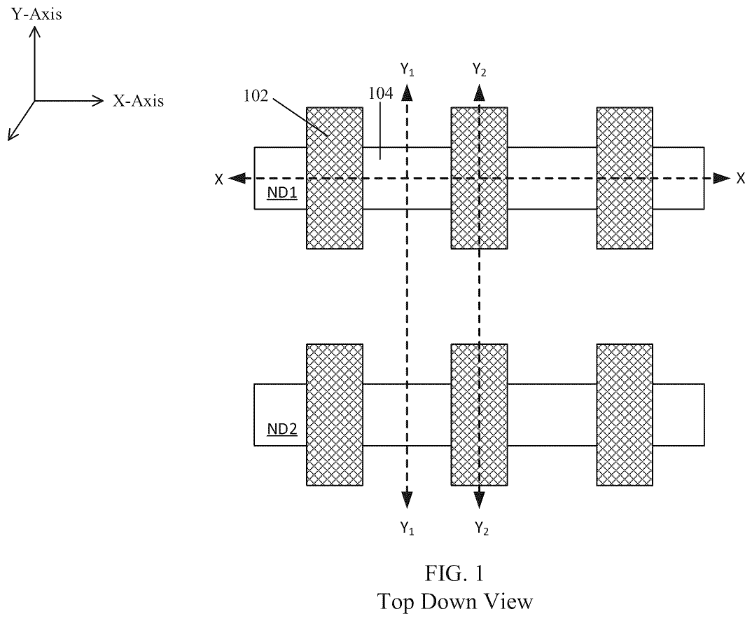

FIG. 1 illustrates a top-down view of a plurality of nanodevices ND1, ND2, in accordance with the embodiment of the present invention. The adjacent and parallel devices include a first nanodevice ND1 including a plurality of first upper transistors and a plurality of first lower transistors, and a second nanodevice ND2 including a plurality of second upper transistors and a plurality of second lower transistors. Cross-section X is a cross section perpendicular to the gates along the horizontal axis of the first nanodevice ND1. Cross-section Y₁ is a cross section parallel to the gates in the source/drain region 104 across the plurality of nanodevices ND1, ND2. Cross-section Y₂ is a cross section parallel to the gates in the gate region 102 across the plurality of nanodevices ND1, ND2. It may be appreciated that the embodiment of the present invention is not limited to nanodevices ND1, ND2 and that other devices including, but not limited to, nanosheet transistors, FinFET, nanowire, and a planar device may also be used.

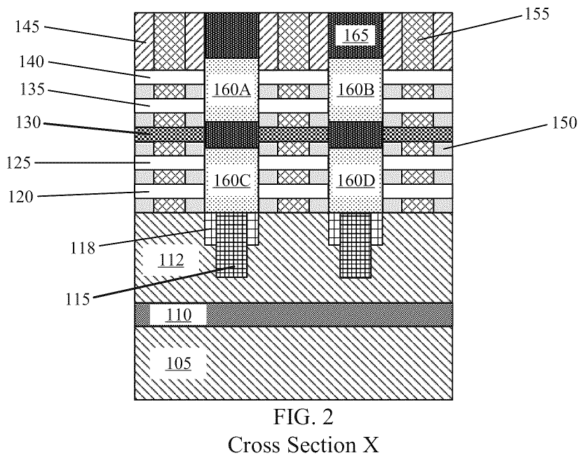

FIGS. 2-4 illustrate cross sections X, Y₁, and Y₂, respectively, of the plurality of nanodevices ND1, ND2 after interlayer dielectric (ILD) 165 deposition, nanosheet 120, 125, 135, 140 formation, shallow trench isolation (STI) region 114 formation, gate 155 formation, gate spacer 145 and inner spacer 150 formation, middle dielectric isolation (MDI) layer 130 formation, source/drain 160A, 160B, 160C, 160D, 160E, 160F formation, etch stop layer 110 formation, sacrificial placeholder 115 formation, protective liner 118 formation, gate cut dielectric pillar 170, 175, 180 formation, and CMP, in accordance with the embodiment of the present invention. The plurality of nanodevices ND1, ND2 include a substrate 105, an etch stop layer 110, an underlying substrate layer 112, an STI region 114, a first lower nanosheet 120, a second lower nanosheet 125, a first upper nanosheet 135, and a second upper nanosheet 140. As used herein, the terms “upper” and “lower” refer to the orientation of structures prior to a wafer flip. Thus, structures above the MDI layer 130 prior to the wafer flip are referred to as “upper” and structures below the MDI layer 130 prior to the wafer flip are referred to as “lower.” The substrate 105 and the etch stop layer 110 can be, for example, a material including, but not necessarily limited to, silicon (Si), silicon germanium (SiGe), Si: C (carbon doped silicon), carbon doped silicon germanium (SiGe: C), III-V, II-V compound semiconductor or another like semiconductor. In addition, multiple layers of the semiconductor materials can be used as the semiconductor material of the substrate 105. In some embodiments, the substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or the entire semiconductor substrate 105 may also be comprised of an amorphous, polycrystalline, or monocrystalline. The semiconductor substrate 105 and the etch stop layer 110 may be doped, undoped or contain doped regions and undoped regions therein. A portion of the underlying substrate layer 112 is selectively removed and a material (e.g., SiGe) is deposited in a space created by the removal of the portion of the underlying substrate layer 112 to form the sacrificial placeholder 115 and the protective liner 118 along a portion of sidewalls of the sacrificial placeholder.

The first sacrificial layer (not shown) is formed directly atop the underlying substrate layer 112. The second sacrificial layer (not shown) is formed directly atop the first sacrificial layer (not shown). The first lower nanosheet 120 is formed directly atop the second sacrificial layer (not shown). The third sacrificial layer (not shown) is formed directly atop the first lower nanosheet 120. The second lower nanosheet 125 is formed directly atop the third sacrificial layer (not shown). The fourth sacrificial layer (not shown) is formed directly atop the second lower nanosheet 125. The MDI layer 130 is formed directly atop the fourth sacrificial layer (not shown). The fifth sacrificial layer (not shown) is formed directly atop the MDI layer 130. The first upper nanosheet 135 is formed directly atop the fifth sacrificial layer (not shown). The sixth sacrificial layer (not shown) is formed directly atop the first upper nanosheet 135. The second upper nanosheet 140 is formed directly atop the sixth sacrificial layer (not shown). The first sacrificial layer (not shown), the second sacrificial layer (not shown), the third sacrificial layer (not shown), the fourth sacrificial layer (not shown), the fifth sacrificial layer (not shown), and the sixth sacrificial layer (not shown) are hereinafter referred to as the plurality of sacrificial layers (not shown). In addition, the first lower nanosheet 120 and the second lower nanosheet 125 are hereinafter referred to as the plurality of lower nanosheets 120, 125, and the first upper nanosheet 135 and the second upper nanosheet 140 are hereinafter referred to as the plurality of upper nanosheets 135, 140. The plurality of sacrificial layers (not shown) may be comprised of, for example, SiGe, where Ge is about 35%. The plurality of lower nanosheets 120, 125 and the plurality of upper nanosheets 135, 140 may be comprised of, for example, Si. The number of nanosheets and the number of sacrificial layers described above are not intended to be limiting, and it may be appreciated that in the embodiment of the present invention the number of nanosheets and the number of sacrificial layers may vary. After formation of the plurality of lower nanosheets 120, 125, the plurality of upper nanosheets 135, 140, and the plurality of sacrificial layers (not shown), together the nanosheet stack, the nanosheet stack (comprising alternative Si and SiGe layers) may be further patterned using conventional lithography and etching processes. After nanosheet stack formation and patterning, the STI region 114 is formed by dielectric filling, CMP, and dielectric recess.

A dummy gate material is deposited and then patterned to form dummy gates (not shown), followed by gate spacer 145 formation by a conformal dielectric liner deposition followed by anisotropic etch. Then, the nanosheet stack at the S/D region 104 is recessed, followed by indentation of sacrificial layers (not shown) and inner spacer 150 formation. Then, the first upper source/drain 160A, the second upper source/drain 160B, the first lower source/drain 160C, the second lower source/drain 160D, the third upper source/drain 160E, and the third lower source/drain 160F are epitaxially grown over exposed sidewalls of the plurality of lower nanosheets 120, 125 and the plurality of upper nanosheets 135, 140, followed by ILD 165 deposition and CMP to remove a dummy gate hard mask (not shown). Then, the sacrificial layers (not shown) are removed, followed by gate 155 formation. The first lower source/drain 160C, the second lower source/drain 160D, and the third lower source/drain 160F are formed directly atop the sacrificial placeholder 115 and the protective liner 118. The first upper source/drain 160A, the second upper source/drain 160B, and the third upper source/drain 160E are formed over the first lower source/drain 160C, the second lower source/drain 160D, and the third lower source/drain 160F, respectively, within the ILD 165.

The first upper source/drain 160A, the second upper source/drain 160B, the first lower source/drain 160C, the second lower source/drain 160D, the third upper source/drain 160E, and the third lower source/drain 160F can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (TI) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

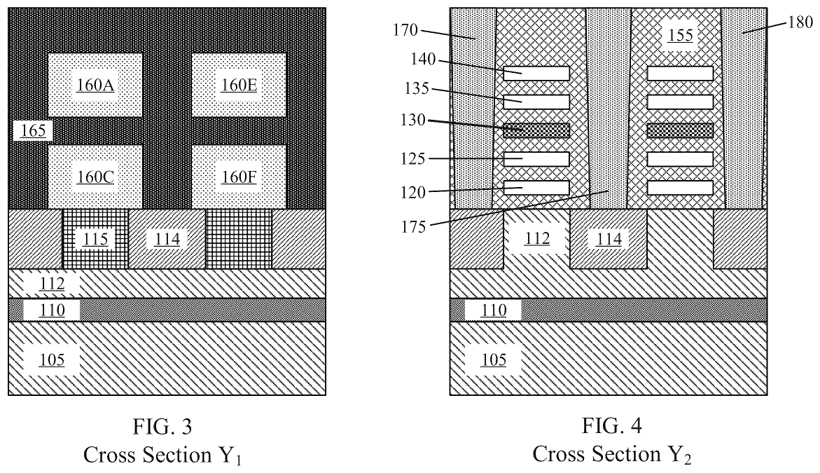

In FIG. 2, the ILD 165 is formed directly atop the first upper source/drain 160A, the second upper source/drain 160B, the first lower source/drain 160C, and the second lower source/drain 160D, and surrounds one side of the gate spacer 145, the MDI layer 130, and a portion of the inner spacer 150. In FIG. 3, the ILD 165 is formed directly atop the first upper source/drain 160A, the first lower source/drain 160C, the third upper source/drain 160E, and the third lower source/drain 160F, and the STI region 114.

In FIG. 2, a gate material is deposited in the space created by the removal of the plurality of sacrificial layers (not shown) and directly atop the second upper nanosheet 140 to form a replacement gate (i.e., the gate 155). In FIG. 4, the gate material is deposited in the space created by the removal of the plurality of sacrificial layers (not shown), and directly atop the second upper nanosheet 140 and the STI region 114 to form the gate 155. The gate 155 can be comprised of, for example, a gate dielectric liner, such as a high-k dielectric like HfO2, ZrO2, HfLaOx, etc., and work function layers, such as TiN, TiAlC, TiC, etc., and conductive metal fills, like W. In FIG. 4, a liner material is also deposited in trenches (not shown) formed during front-end-of-line processing to form the first gate cut dielectric pillar 170, the second gate cut dielectric pillar 175, and the third gate cut dielectric pillar 180. The liner material may be comprised of, for example, SiN, SiBCN, SiOCN, SiOC, or SiC.

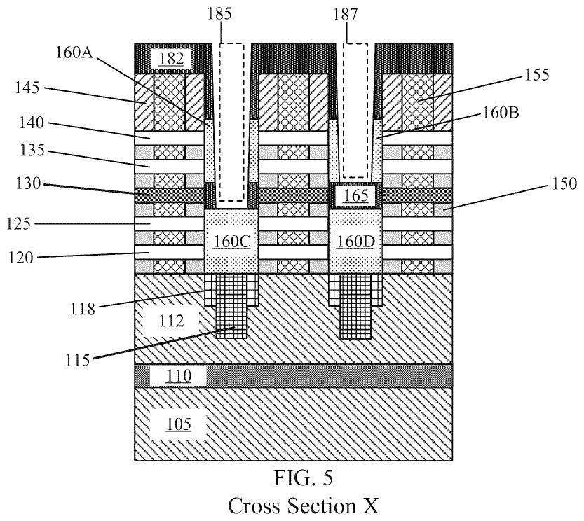

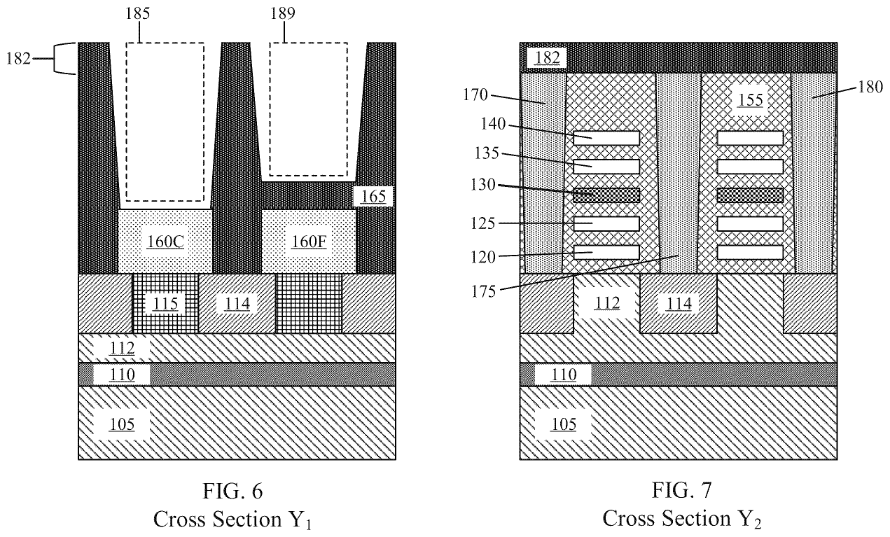

FIGS. 5-7 illustrate cross sections X, Y₁, and Y₂, respectively, of the plurality of nanodevices ND1, ND2 after the formation of a first trench 185, a second trench 187, and a third trench 189, in accordance with the embodiment of the present invention. In FIG. 5, an additional ILD 182 is formed directly atop the gate spacer 145, the gate 155, and the ILD 165. A portion of the ILD 165, the additional ILD 182, and the first upper source/drain 160A are etched by, for example, RIE to form the first trench 185. A bottom surface of the first trench 185 exposes a portion of a top surface of the first lower source/drain 160C. A portion of the second upper source/drain 160B and different portions of the ILD 165 and the additional ILD 182 are etched by, for example, RIE to form the second trench 187. A bottom surface of the second trench 187 exposes a portion of a top surface of the ILD 165. In FIG. 6, the additional ILD 182 is formed directly atop the ILD 165. A portion of the ILD 165 and the additional ILD 182 are etched by, for example, RIE to form the first trench 185. A bottom surface of the first trench 185 exposes a portion of the top surface of the first lower source/drain 160C. Different portions of the ILD 165 and the additional ILD 182 are etched by, for example, RIE to form the third trench 189. A bottom surface of the third trench 189 exposes a different portion of the top surface of the ILD 165. In FIG. 7, the additional ILD 182 is formed directly atop the gate 155, the first gate cut dielectric pillar 170, the second gate cut dielectric pillar 175, and the third gate cut dielectric pillar 180.

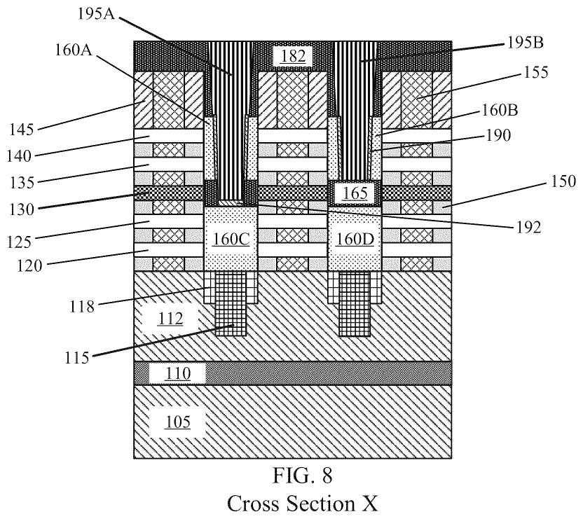

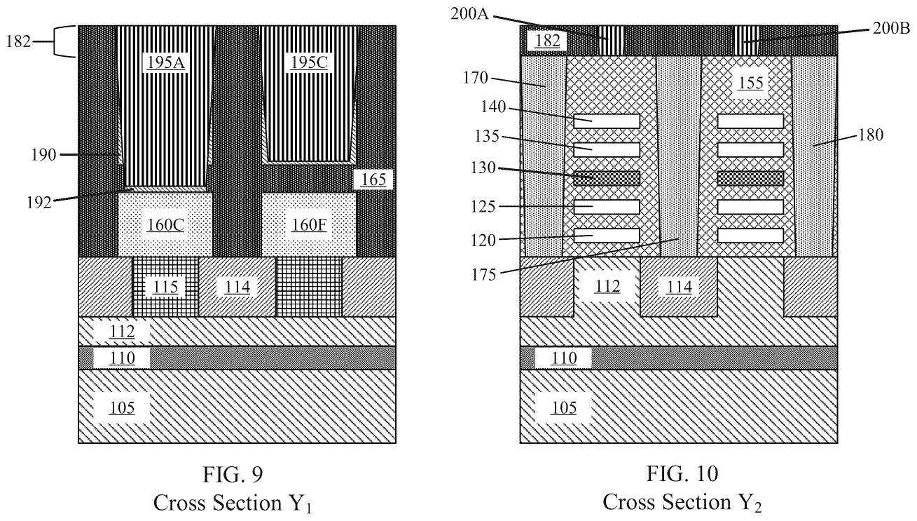

FIGS. 8-10 illustrate cross sections X, Y₁, and Y₂, respectively, of the plurality of nanodevices ND1, ND2 after the formation of a first source/drain contact 195A, a first independent source drain contact 195B, a second independent source/drain contact 195C, a plurality of gate contacts 200A, 200B, and frontside silicide liners 190, 192, in accordance with the embodiment of the present invention. In FIG. 8, the first trench 185 (FIG. 5) and the second trench 187 (FIG. 5) are filled with a conductive metal (e.g., including a silicide liner, such as Ni, Ti, NiPt, an adhesion metal liner, such as TiN and conductive metal fill, such as W, Co, or Ru) to form the first source/drain contact 195A, the first independent source/drain contact 195B, the first frontside silicide liner 190 (i.e., the frontside silicide liner in the claims), and the second frontside silicide liner 192. The first source/drain contact 195A is located over the first lower source/drain 160C. The first independent source/drain contact 195B is located over the second lower source/drain 160D. In FIG. 9, the first trench 185 (FIG. 6) and the third trench 189 (FIG. 6) are filled with the conductive metal to form the first source/drain contact 195A, the second independent source/drain contact 195C, the first frontside silicide liner 190, and the second frontside silicide liner 192. The first source/drain contact is located over the first lower source/drain 160C. The second independent source/drain contact 195 is located over the third lower source/drain 160F. In FIG. 10, a plurality of trenches (not shown) formed during middle-of-line (MOL) patterning are filled with the conductive metal to form the plurality of gate contacts 200A, 200B. The first gate contact 200A is located directly atop the gate 155 between the first gate cut dielectric pillar 170 and the second gate cut dielectric pillar 175. The second gate contact is located directly atop the gate 155 between the second gate cut dielectric pillar 175 and the third gate cut dielectric pillar 180.

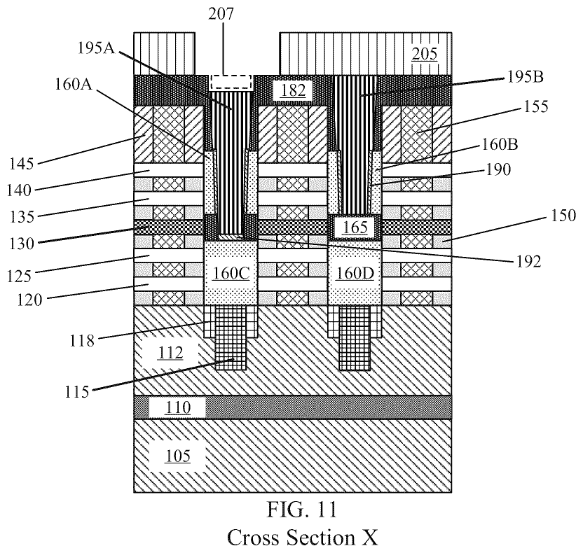

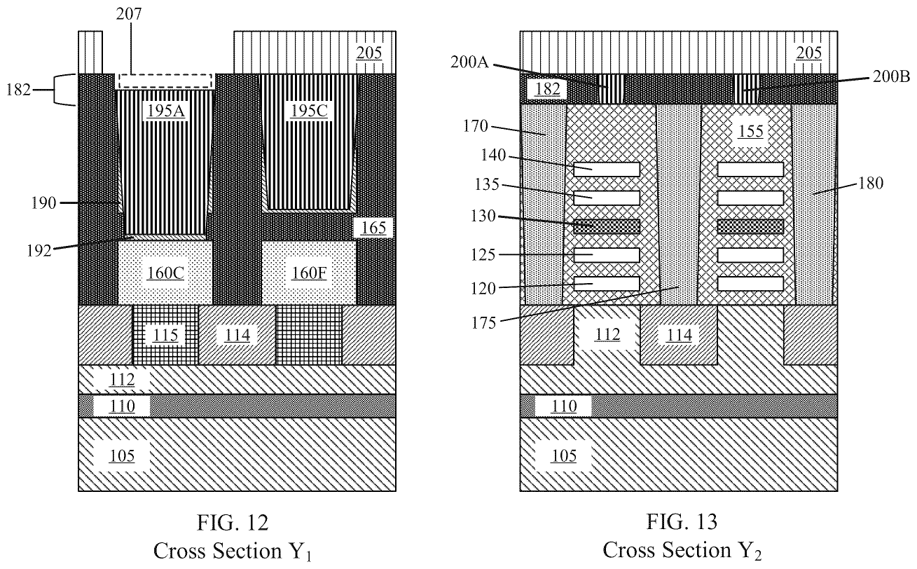

FIGS. 11-13 illustrate cross sections X, Y₁, and Y₂, respectively, of the plurality of nanodevices ND1, ND2 after the formation of a lithography mask layer 205 and a fourth trench 207, in accordance with the embodiment of the present invention. The lithography mask layer 205 may be, for example, an organic planarization layer (OPL). In FIG. 11, the lithography mask layer 207 is deposited and then patterned directly atop the additional ILD 182, the first source/drain contact 195A, and the first independent source/drain contact 195B to expose a portion of the underlying additional ILD 182 and the first source/drain contact 195A. The exposed portion of the first source/drain contact 195A is etched by, for example, RIE to form the fourth trench 207. A bottom surface of the fourth trench 207 exposes a top surface of the first source/drain contact 195A. In FIG. 12, the lithography mask layer 205 is deposited and then patterned directly atop the additional ILD 182, the first source/drain contact 195A, and the second independent source/drain contact 195C to expose a portion of the underlying additional ILD 182 and the first source/drain contact 195A. The exposed portion of the first source/drain contact 195A is etched by, for example, RIE to form the fourth trench 207. A bottom surface of the fourth trench 207 exposes the top surface of the first source/drain contact 195A. In FIG. 13, the lithography mask layer 205 is deposited directly atop the additional ILD 182, the first gate contact 200A, and the second gate contact 200B. In FIGS. 11-13, the lithography mask layer 205 is formed by depositing, for example, an OPL material in a spin-on coating process.

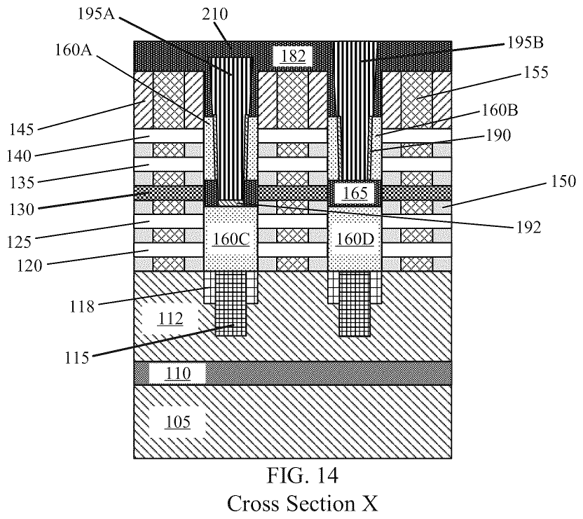

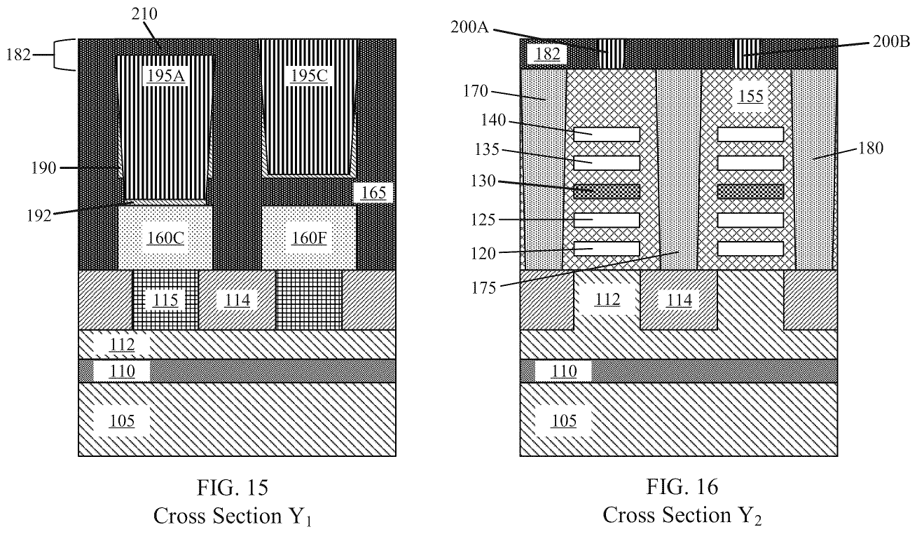

FIGS. 14-16 illustrate cross sections X, Y₁, and Y₂, respectively, of the plurality of nanodevices ND1, ND2 after the formation of an isolation ILD 210 and CMP, in accordance with the embodiment of the present invention. The lithography mask layer 205 is removed. A dielectric material is deposited in the fourth trench 207 (FIGS. 11-12) to form the isolation ILD 210. The isolation ILD 210 is located directly atop the first source/drain contact 195A and may be comprised of a same material as the ILD 165 and the additional ILD 182. A portion of the isolation ILD 210 is removed by, for example, CMP.

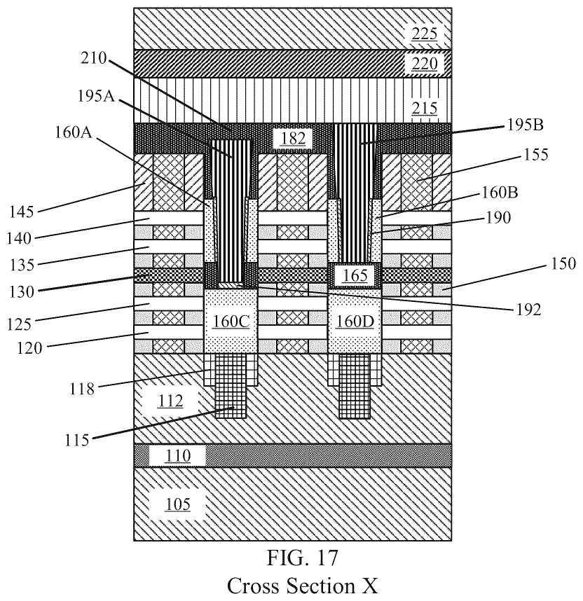

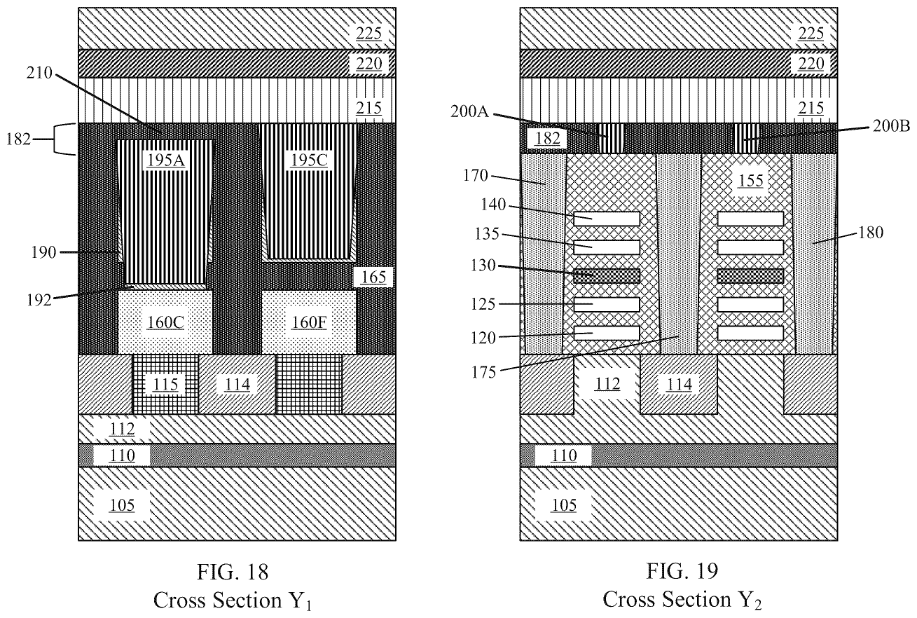

FIGS. 17-19 illustrate cross sections X, Y₁, and Y₂, respectively, of the plurality of nanodevices ND1, ND2 after the formation of a back-end-of-line (BEOL) layer 215, a bonding oxide layer 220, and bonding to a carrier wafer 225, in accordance with the embodiment of the present invention. The BEOL layer 215 may contain multiple metal layers and vias in between. In FIG. 17, the BEOL layer 215 is formed directly atop the additional ILD 182, the isolation ILD 210, and the first independent source/drain contact 195B. In FIG. 18, the BEOL layer 215 is formed directly atop the additional ILD 182, the isolation ILD 210, and the second independent source/drain contact 195C. In FIG. 19, the BEOL layer 215 is formed directly atop the additional ILD 182, the first gate contact 200A, and the second gate contact 200B. In FIGS. 17-19, the bonding oxide layer 220 is formed directly atop the BEOL layer 215. The carrier wafer 225 is formed directly atop the bonding oxide layer 220 by bonding processes (e.g., oxide-oxide bonding).

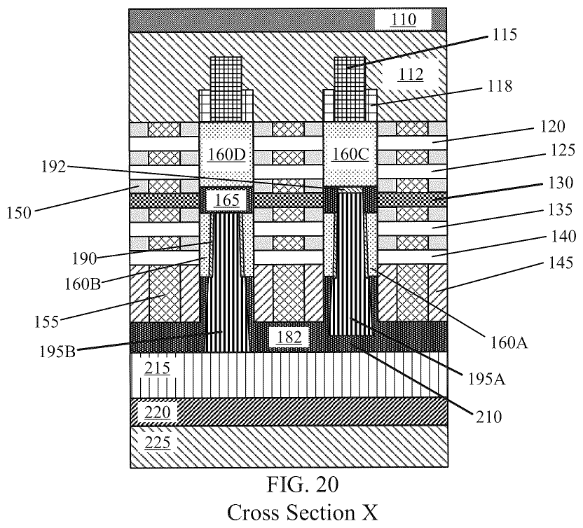

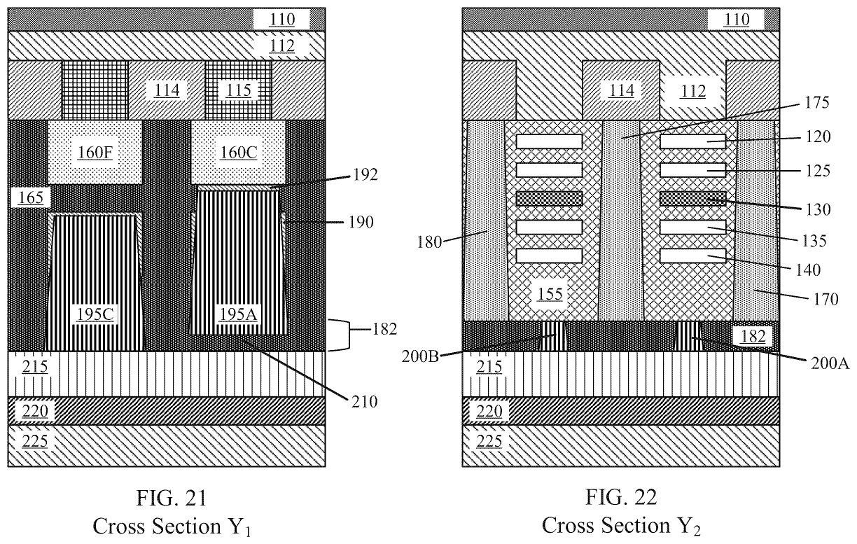

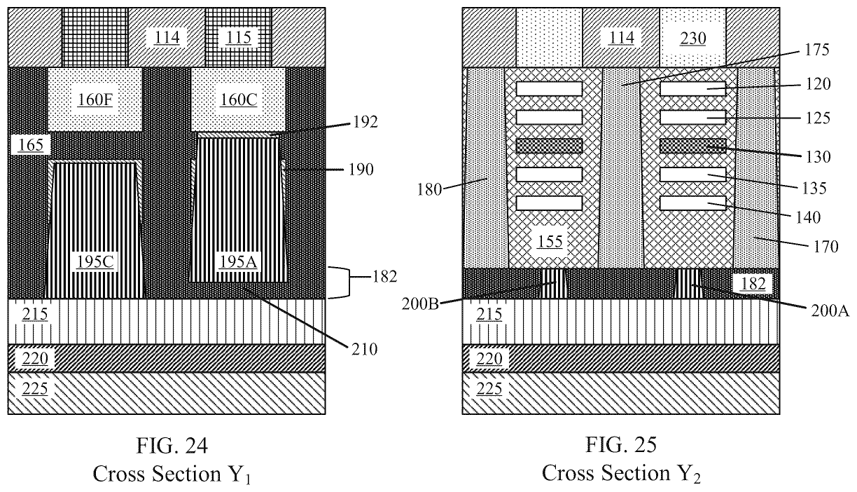

FIGS. 1-19 illustrate the processing of the frontside of the substrate 105, while FIGS. 20-37 illustrate the processing of the backside of the substrate 105. FIGS. 20-22 illustrate cross sections X, Y₁, and Y₂, respectively, of the plurality of nanodevices ND1, ND2 after the carrier wafer 225 is flipped and the substrate 105 is removed, in accordance with the embodiment of the present invention. The carrier wafer 225 is flipped and the carrier wafer 225 becomes a handler wafer. The substrate 105 is removed by, for example, a combination of processes such as wafer grinding, CMP, and/or selective dry/wet etch, stopping on the etch stop layer 110.

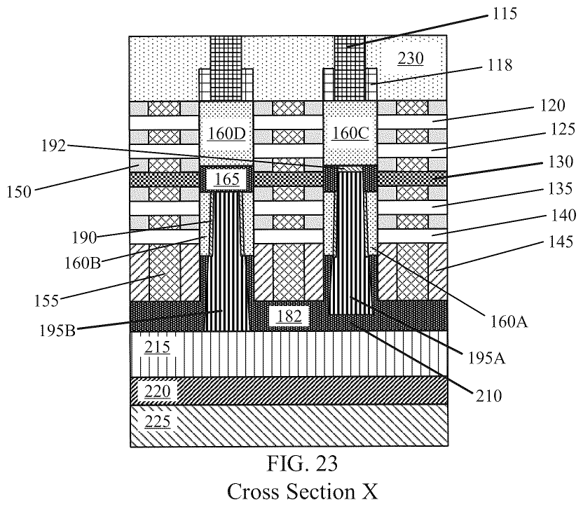

FIGS. 23-25 illustrate cross sections X, Y₁, and Y₂, respectively, of the plurality of nanodevices ND1, ND2 after the removal of the etch stop layer 110 and the underlying substrate layer 112, backside ILD (BILD) layer 230 deposition, and CMP, in accordance with the embodiment of the present invention. The etch stop layer 110 is removed to expose the underlying substrate layer 112. The underlying substrate layer 112 is removed by, for example, a selective wet or dry etch process.

The BILD layer 230 may be comprised of, for example, SiC or SiOC. In FIG. 23, the BILD layer 230 is deposited directly atop the inner spacer 150, the gate 155, and the protective liner 118. In FIG. 25, the BILD layer 230 is deposited directly atop the gate 155. In FIGS. 23 and 25, a portion of the BILD layer 230 is selectively removed by, for example, CMP.

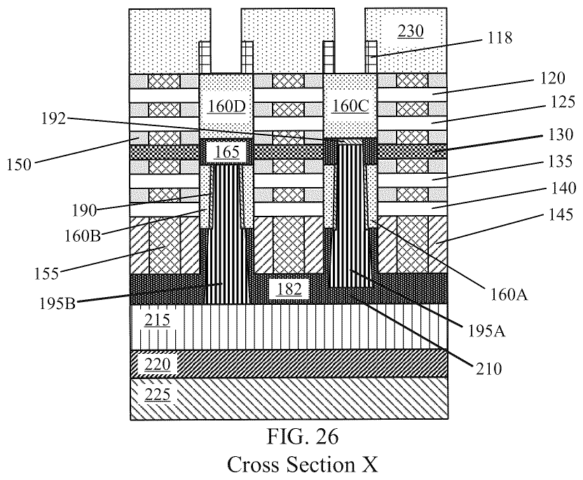

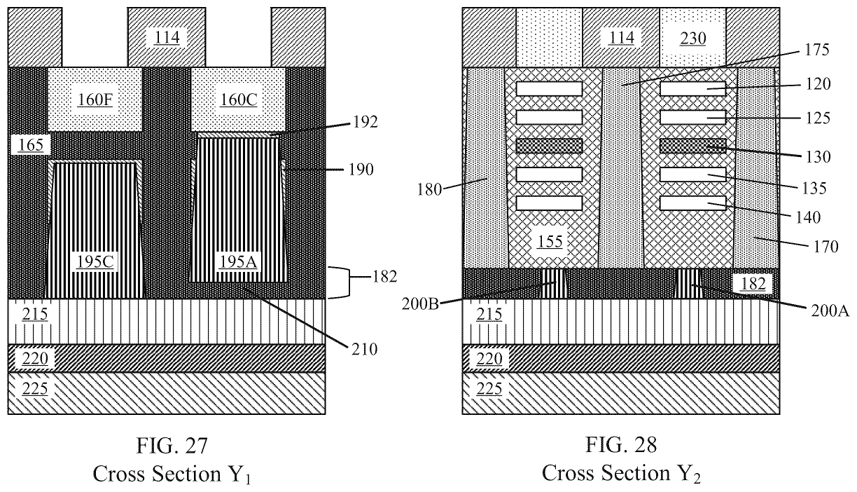

FIGS. 26-28 illustrate cross sections X, Y₁, and Y₂, respectively, of the plurality of nanodevices ND1, ND2 after the removal of the sacrificial placeholder 115, in accordance with the embodiment of the present invention. In FIG. 26, the sacrificial placeholder 115 is removed by, for example, CMP to expose a portion of a top surface of the first lower source/drain 160C and the second lower source/drain 160D. In FIG. 27, the sacrificial placeholder 115 is removed by, for example, CMP to expose a portion of the top surface of the first lower source/drain 160C and the third lower source/drain 160F.

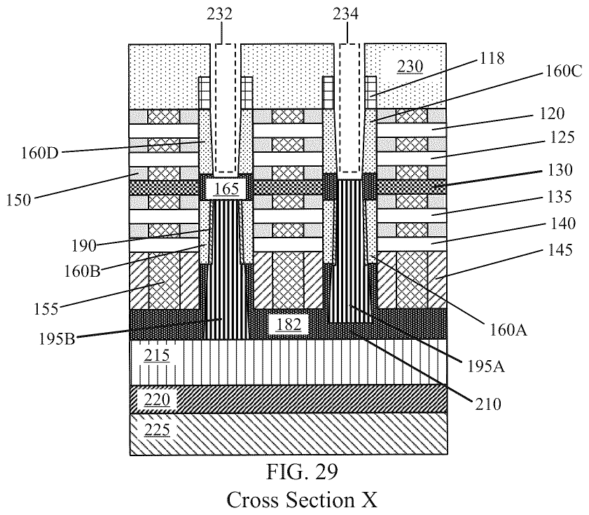

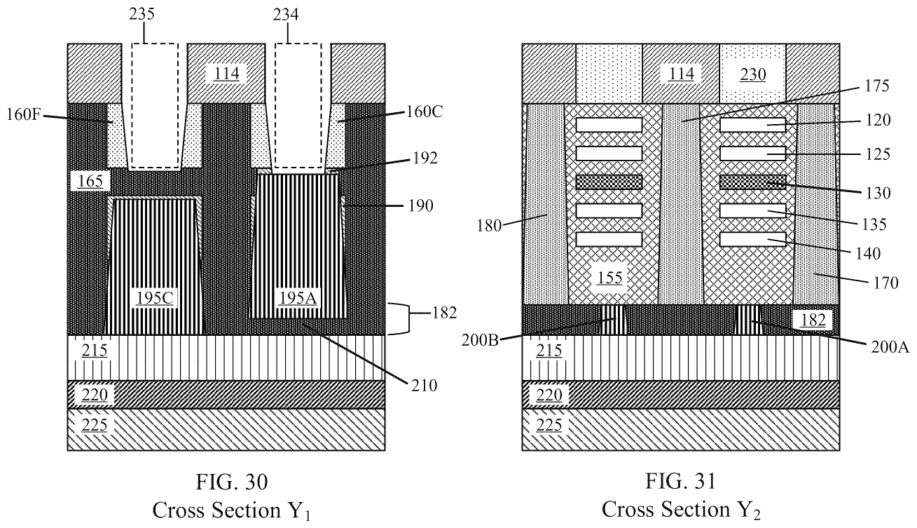

FIGS. 29-31 illustrate cross sections X, Y₁, and Y₂, respectively, of the plurality of nanodevices ND1, ND2 after the formation of a fifth trench 232, a sixth trench 234, and a seventh trench 235, in accordance with the embodiment of the present invention. In FIG. 29, a portion of the second lower source/drain 160D and the second frontside silicide liner 192 are etched by, for example, RIE to form the fifth trench 232. A bottom surface of the fifth trench 232 exposes a portion of a top surface of the ILD 165. A portion of the first lower source/drain 160C is etched by, for example, RIE to form the sixth trench 234. A bottom surface of the sixth trench 234 exposes a top surface of the first source/drain contact 195A. In FIG. 30, a portion of the first lower source/drain 160C is etched by, for example, RIE to form the sixth trench 234. The bottom surface of the sixth trench 234 exposes the top surface of the first source/drain contact 195A. A portion of the third lower source/drain 160F is etched by, for example, RIE to form the seventh trench 235. A bottom surface of the seventh trench 235 exposes a portion of a top surface of the ILD 165.

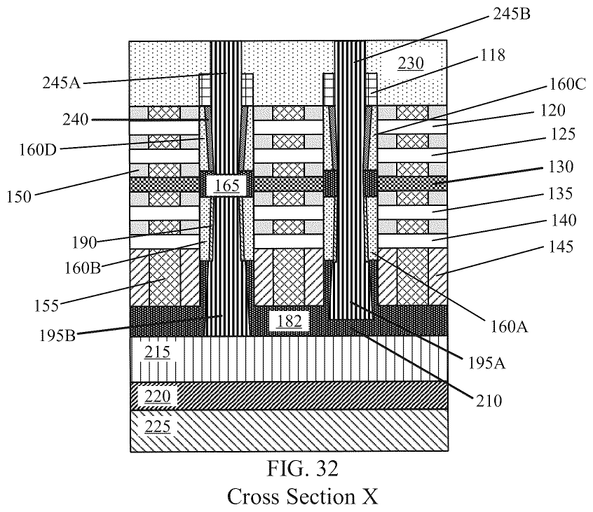

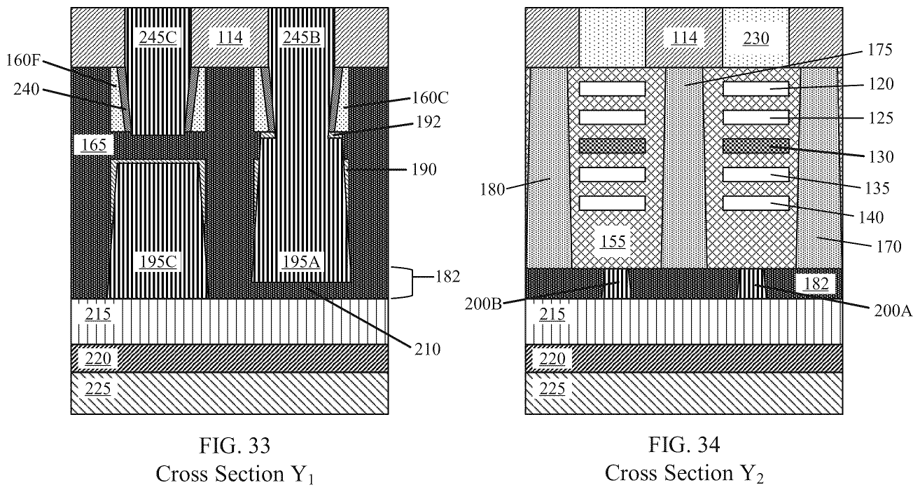

FIGS. 32-34 illustrate cross sections X, Y₁, and Y₂, respectively, of the plurality of nanodevices ND1, ND2 after the formation of a second source/drain contact 245B, a second independent backside source/drain contact 245A, a third independent backside source/drain contact 245C, and a backside silicide liner 240, in accordance with the embodiment of the present invention. In FIG. 32, the fifth trench 232 (FIG. 29) and the sixth trench 234 (FIG. 29) are filled with the conductive metal (e.g., including a silicide liner, such as Ni, Ti, NiPt, an adhesion metal liner, such as TiN and conductive metal fill, such as W, Co, or Ru) to form the second source/drain contact 245B, the first independent backside source/drain contact 245A, and the backside silicide liner 240. The second source/drain contact 245B directly connects to the first source/drain contact 195A to form the shared source/drain contact 195A, 245B. The first independent backside source/drain contact 245A is located over the first independent source/drain contact 195B. In FIG. 33, the sixth trench 234 (FIG. 30) and the seventh trench 235 (FIG. 30) are filled with the conductive metal to form the second source/drain contact 245B, the second independent backside source/drain contact 245C, and the backside silicide liner 240. The second source/drain contact 245B directly connects to the first source/drain contact 195A to form the shared source/drain contact 195A, 245B. The second independent backside source/drain contact 245C is located over the second independent source/drain contact 195C.

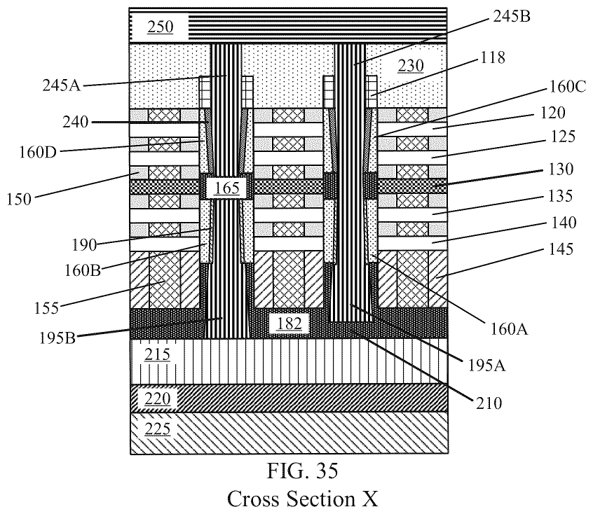

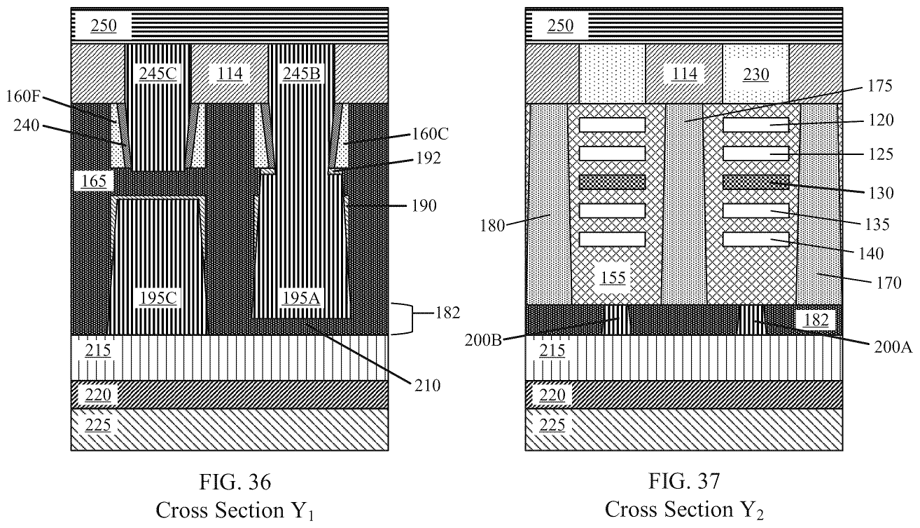

FIGS. 35-37 illustrate cross sections X, Y₁, and Y₂, respectively, of the plurality of nanodevices ND1, ND2 after the formation of a backside interconnect 250, in accordance with the embodiment of the present invention. In FIG. 35, the backside interconnect 250 is formed directly atop the shared source/drain contact 195A, 245B and the first independent backside source/drain contact 245A. In FIG. 36, the backside interconnect 250 is formed directly atop the shared source/drain contact 195A, 245B and the second independent backside source/drain contact 245C. In FIG. 37, the backside interconnect 250 is formed directly atop the STI region 114 and the BILD layer 230.

The shared source/drain contact 195A, 245B extends through the first upper source/drain 160A and the first lower source/drain 160C. the first frontside silicide liner 190 is located along a first portion of sidewalls of the shared source/drain contact 195A, 245B where the shared source/drain contact 195A, 245B passes through the upper source/drain 160A. The backside silicide liner 240 is located along a second portion of the sidewalls of the shared source/drain contact 195A, 245B where the shared source/drain contact 195A, 245B passes through the first lower source/drain 160C. The first frontside silicide liner 190 and the backside silicide liner 240 are comprised of a different material. The first frontside silicide liner 190 may be comprised of, for example, NiPt, whereas the backside silicide liner 240 may be comprised of, for example, Ti. The first independent source/drain contact 195B extends upwards through the second upper source/drain 160B. The second independent source/drain contact 195C extends upwards through the third upper source/drain 160E (FIG. 3). The first independent backside source/drain contact 245A extends downwards through the second lower source/drain 160D. The second independent backside source/drain contact extends downwards through the third lower source/drain 160F.

The isolation ILD 210 includes a frontside isolation ILD 210 in direct contact with a frontside surface of the shared source/drain contact 195A, 245B. The BEOL layer 215 is in direct contact with a frontside surface of the frontside isolation ILD 210, a frontside surface of the first independent source/drain contact 195B, and a frontside surface of the second independent source/drain contact 195C.

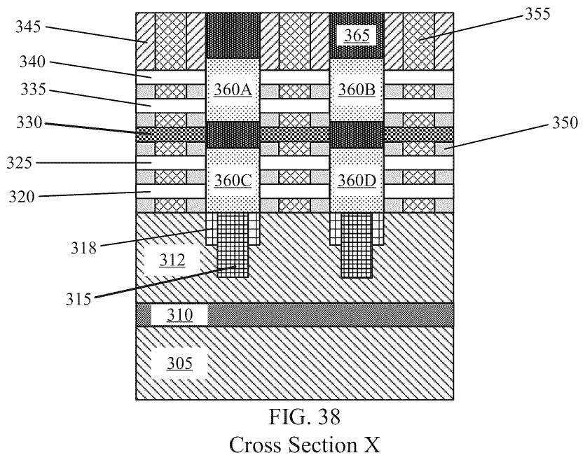

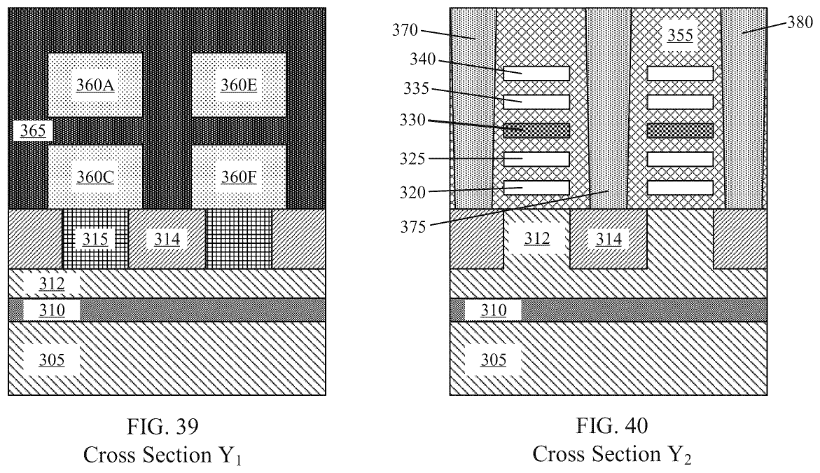

FIGS. 38-40 illustrate cross sections X, Y₁, and Y₂, respectively, of the plurality of nanodevices ND1, ND2 after ILD 365 deposition, nanosheet 320, 325, 335, 340 formation, STI region 314 formation, gate 355 formation, gate spacer 345 and inner spacer 350 formation, MDI layer 330 formation, source/drain 360A, 360B, 360C, 360D, 360E, 360F formation, etch stop layer 310 formation, sacrificial placeholder 315 formation, protective liner 318 formation, gate cut dielectric pillar 370, 375, 380 formation, and CMP, in accordance with the embodiment of the present invention. The plurality of nanodevices ND1, ND2 include the substrate 305, the etch stop layer 310, the underlying substrate layer 312, the STI region 314, the first lower nanosheet 320, the second lower nanosheet 325, the first upper nanosheet 335, and the second upper nanosheet 340.

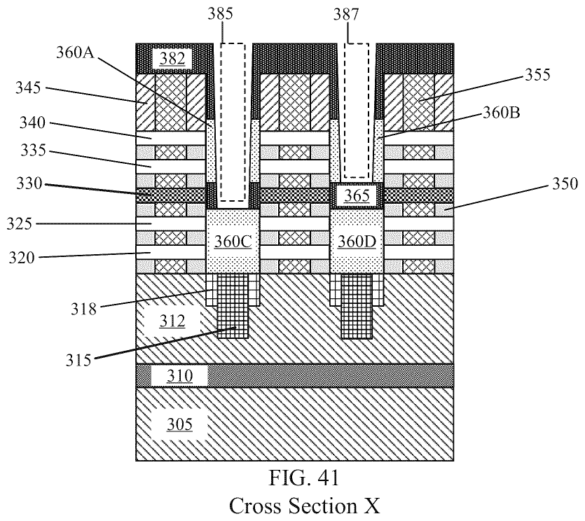

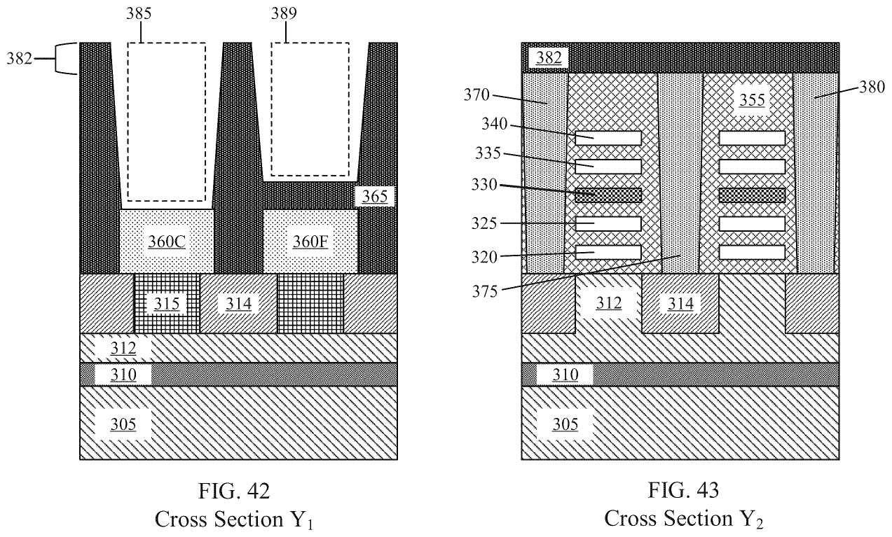

FIGS. 41-43 illustrate cross sections X, Y₁, and Y₂, respectively, of the plurality of nanodevices ND1, ND2 after the formation of the first trench 385, the second trench 387, and the third trench 389, in accordance with the embodiment of the present invention. In FIG. 41, the additional ILD 382 is formed directly atop the gate spacer 345, the gate 355, and the ILD 365. In FIG. 42, the additional ILD 382 is formed directly atop the ILD 365. In FIG. 43, the additional ILD 382 is formed directly atop the gate 355, the first gate cut dielectric pillar 370, the second gate cut dielectric pillar 375, and the third gate cut dielectric pillar 380.

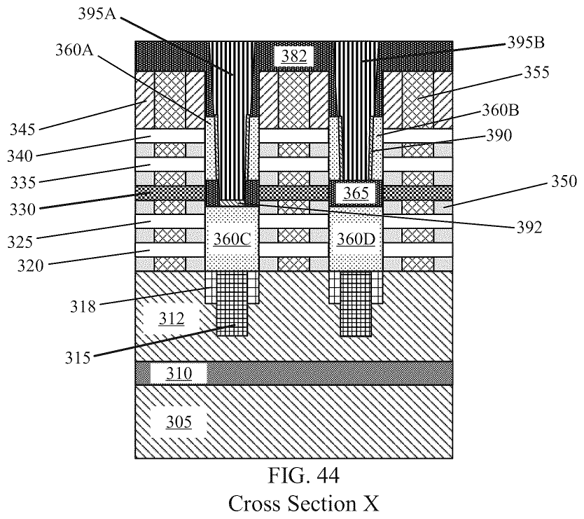

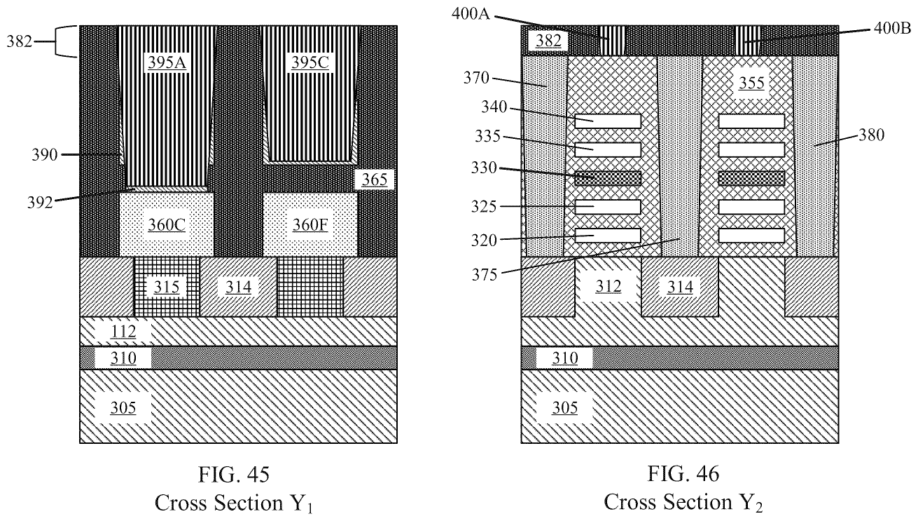

FIGS. 44-46 illustrate cross sections X, Y₁, and Y₂, respectively, of the plurality of nanodevices ND1, ND2 after the formation of the first source/drain contact 395A, the first independent source drain contact 395B, the second independent source/drain contact 395C, the plurality of gate contacts 400A, 400B, and the frontside silicide liners 390, 392, in accordance with the embodiment of the present invention.

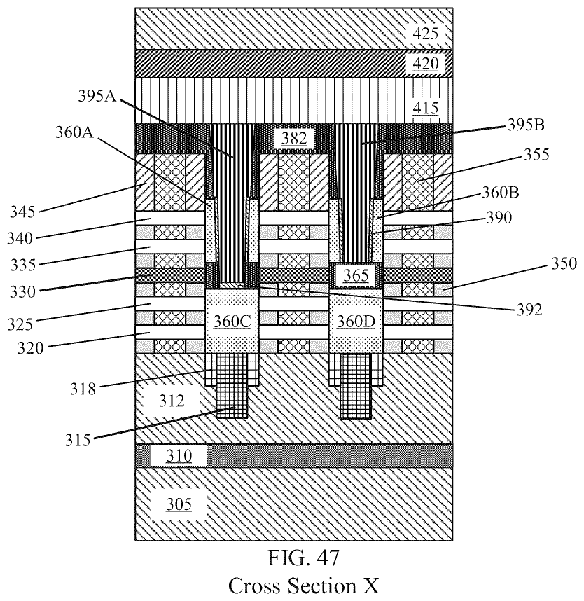

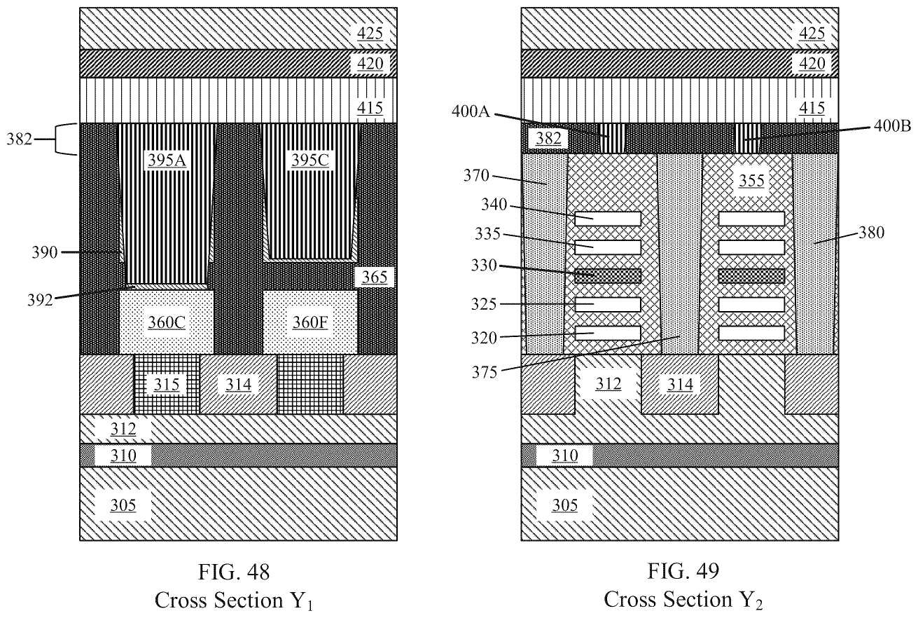

FIGS. 47-49 illustrate cross sections X, Y₁, and Y₂, respectively, of the plurality of nanodevices ND1, ND2 after the formation of the BEOL layer 415, the bonding oxide layer 420, and bonding to the carrier wafer 425, in accordance with the embodiment of the present invention.

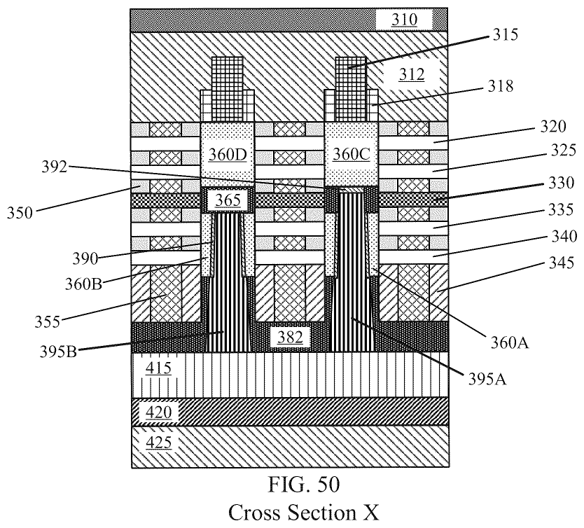

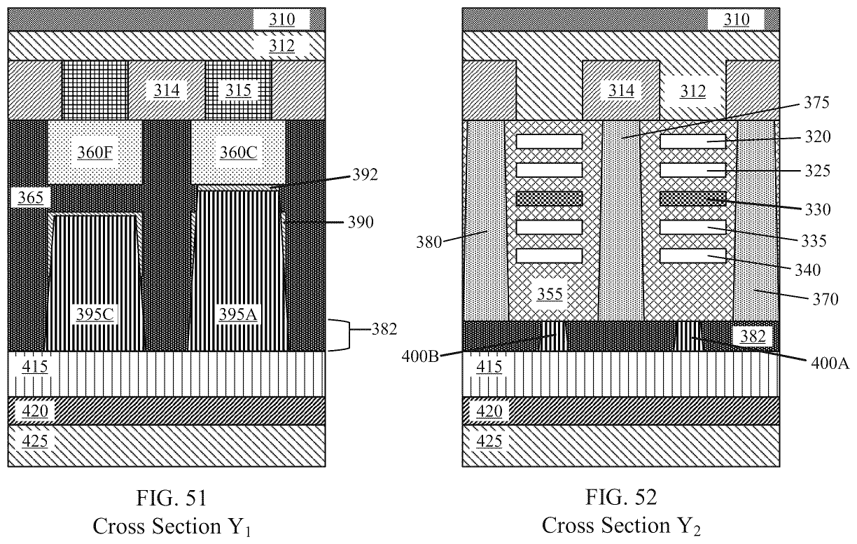

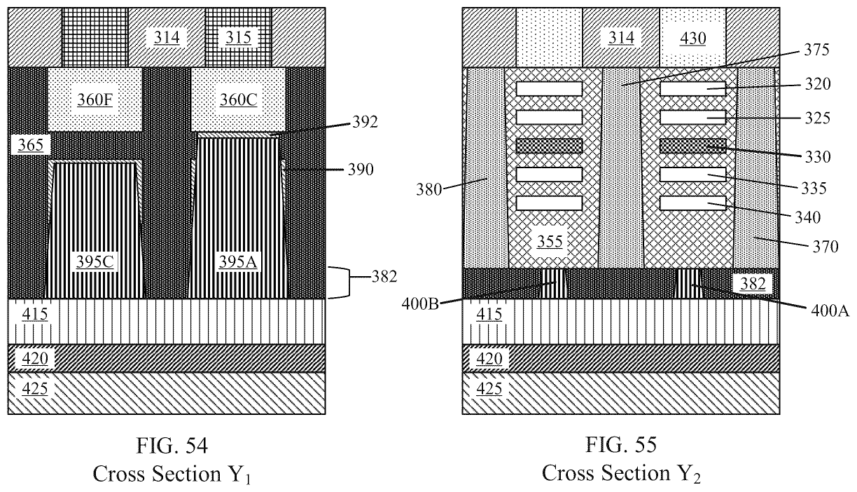

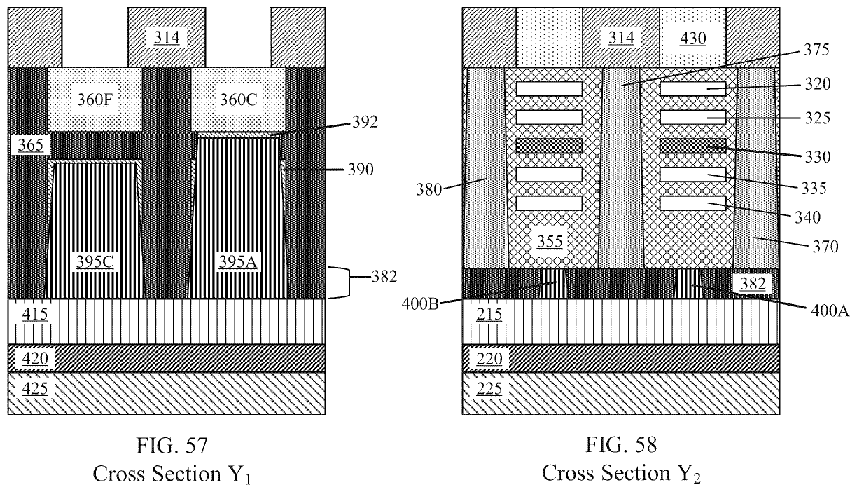

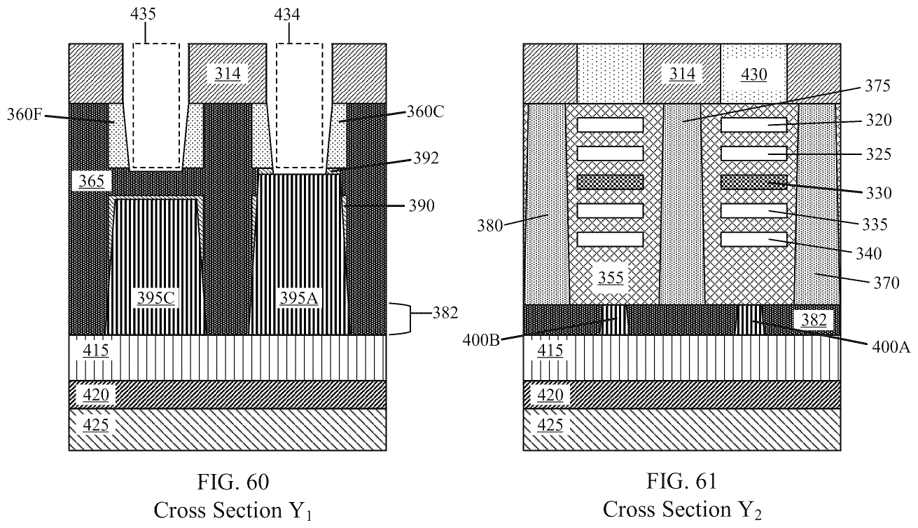

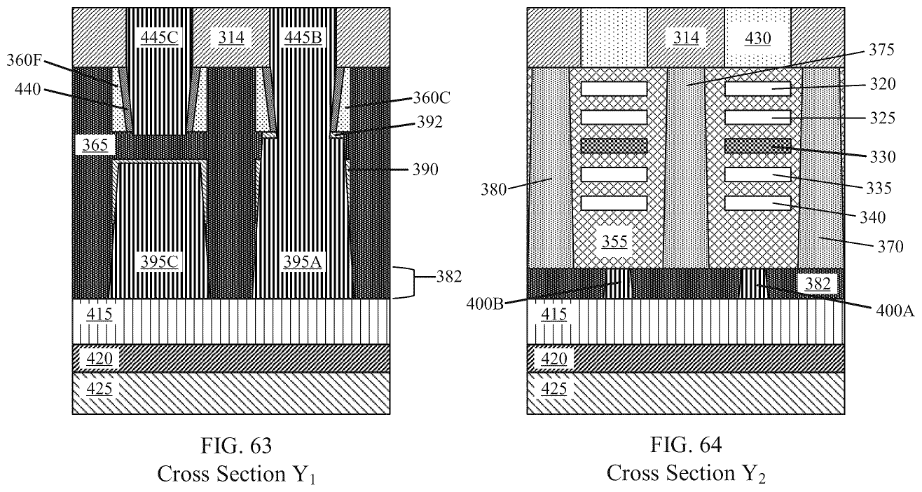

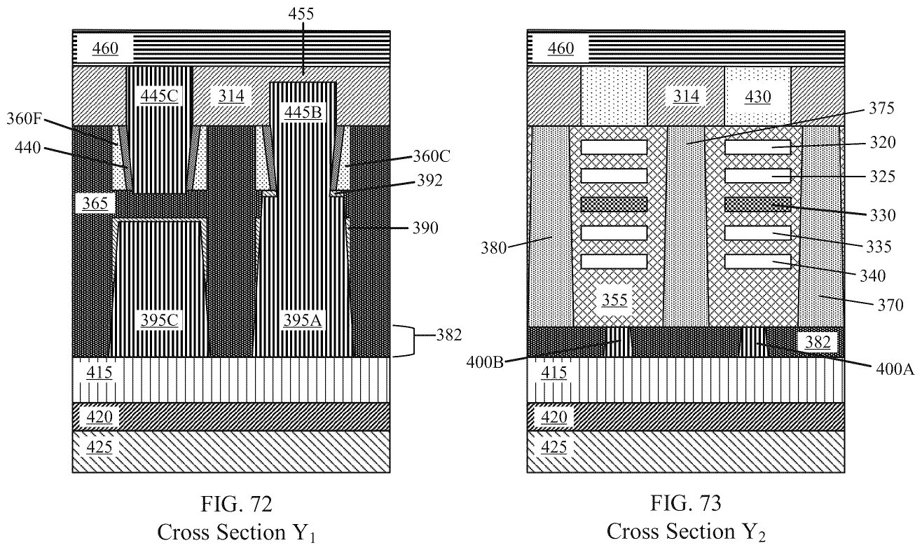

FIGS. 38-49 illustrate the processing of the frontside of the substrate 305, while FIGS. 50-73 illustrate the processing of the backside of the substrate 305. FIGS. 50-52 illustrate cross sections X, Y₁, and Y₂, respectively, of the plurality of nanodevices ND1, ND2 after the carrier wafer 425 is flipped and the substrate 305 is removed, in accordance with the embodiment of the present invention.

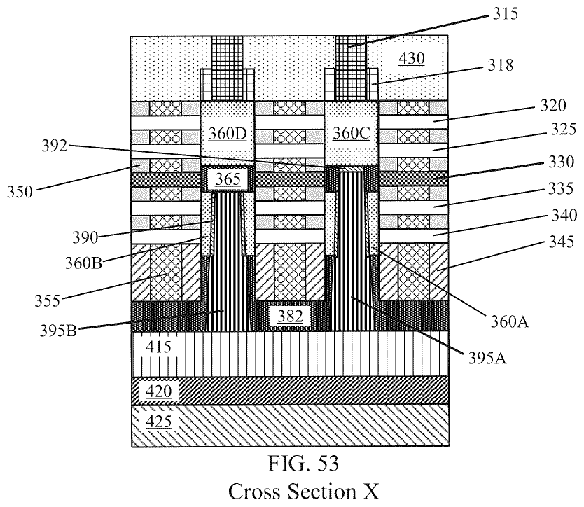

FIGS. 53-55 illustrate cross sections X, Y₁, and Y₂, respectively, of the plurality of nanodevices ND1, ND2 after the removal of the etch stop layer 310 and the underlying substrate layer 312, BILD layer 430 deposition, and CMP, in accordance with the embodiment of the present invention.

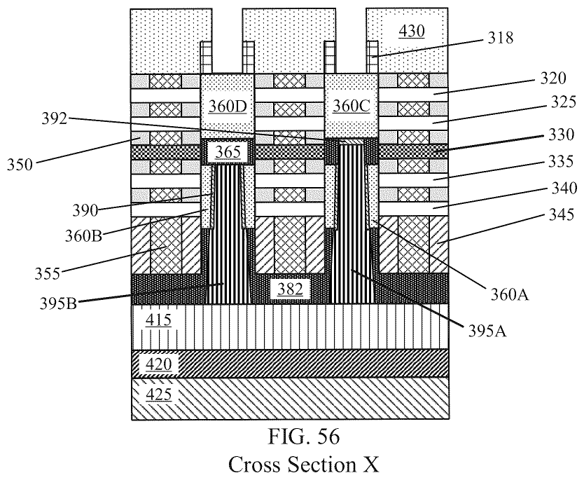

FIGS. 56-58 illustrate cross sections X, Y₁, and Y₂, respectively, of the plurality of nanodevices ND1, ND2 after the removal of the sacrificial placeholder 315, in accordance with the embodiment of the present invention.

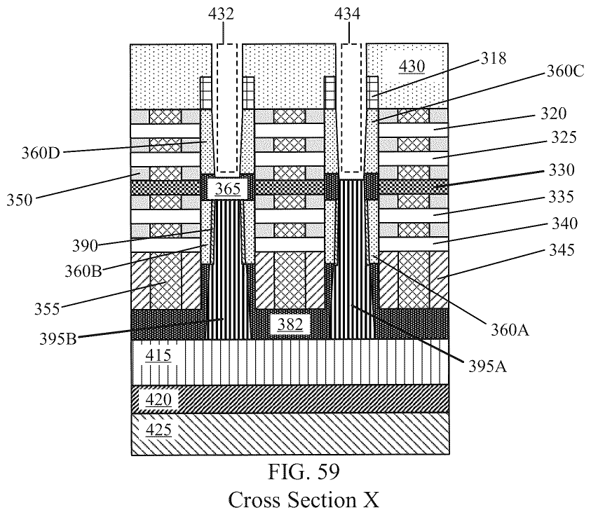

FIGS. 59-61 illustrate cross sections X, Y₁, and Y₂, respectively, of the plurality of nanodevices ND1, ND2 after the formation of the fifth trench 432, the sixth trench 434, and the seventh trench 435, in accordance with the embodiment of the present invention.

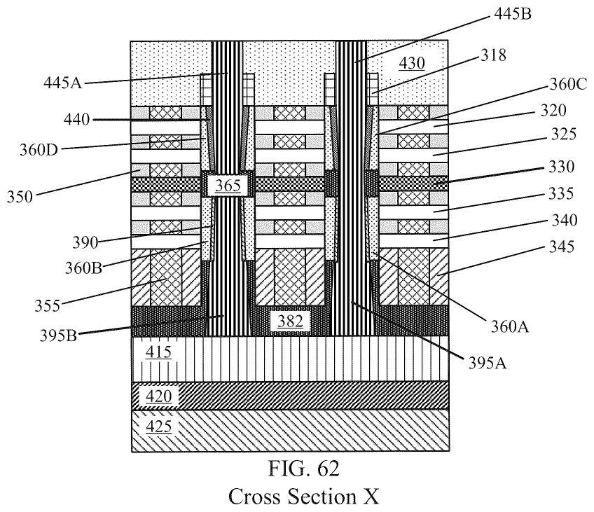

FIGS. 62-64 illustrate cross sections X, Y₁, and Y₂, respectively, of the plurality of nanodevices ND1, ND2 after the formation of the second source/drain contact 445B, the second independent backside source/drain contact 445A, the third independent backside source/drain contact 445C, and the backside silicide liner 440, in accordance with the embodiment of the present invention.

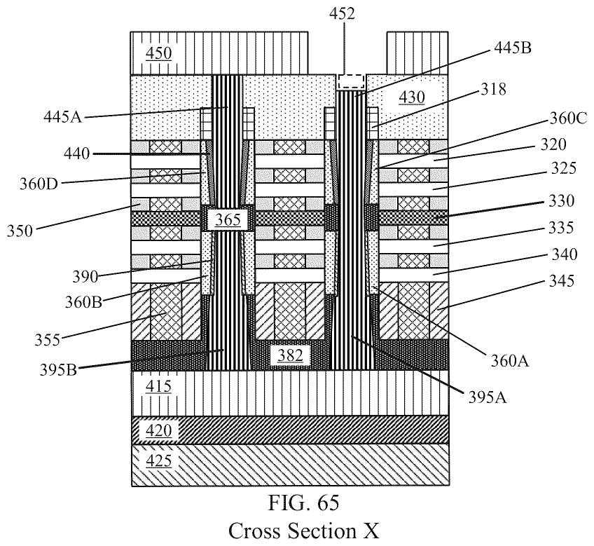

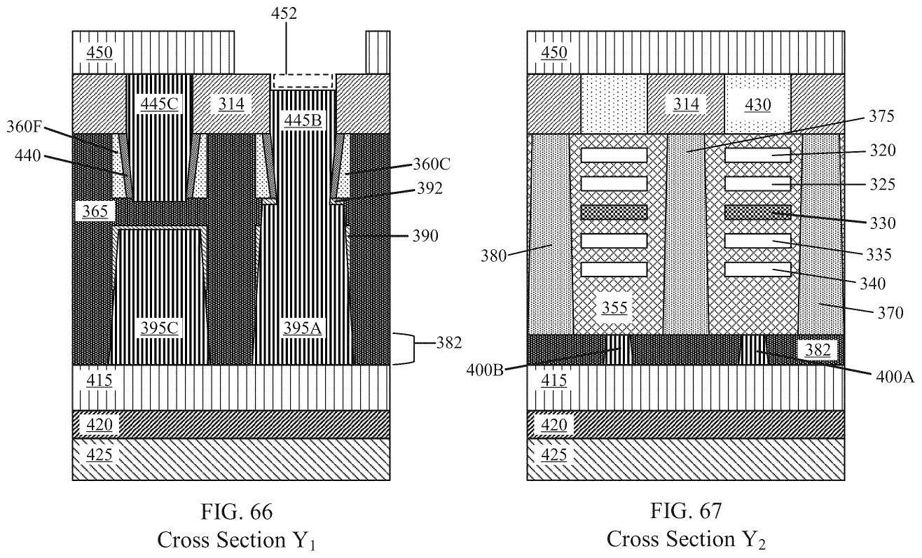

FIGS. 65-67 illustrate cross sections X, Y₁, and Y₂, respectively, of the plurality of nanodevices ND1, ND2 after the formation of a second lithography mask layer 450 and an eighth trench 452, in accordance with the embodiment of the present invention. The second lithography mask layer 450 may be, for example, an OPL. In FIG. 65, the second lithography mask layer 450 is deposited and then patterned directly atop the BILD layer 430, the second source/drain contact 445B, and the first independent backside source/drain contact 445A to expose a portion of the underlying second source/drain contact 445B. The exposed portion of the second source/drain contact 445B is etched by, for example, RIE to form the eighth trench 452. A bottom surface of the eighth trench 452 exposes a top surface of the second source/drain contact 445B. In FIG. 66, the second lithography mask layer 450 is deposited and then patterned directly atop the STI region 314, the second source/drain contact 445B, and the second independent backside source/drain contact 445C to expose a portion of the underlying second source/drain contact 445B. The exposed portion of the second source/drain contact 445B is etched by, for example, RIE to form the eighth trench 452. A bottom surface of the eighth trench 452 exposes the top surface of the second source/drain contact 445B. In FIG. 67, the second lithography mask layer 450 is deposited directly atop the STI region 314 and the BILD layer 430.

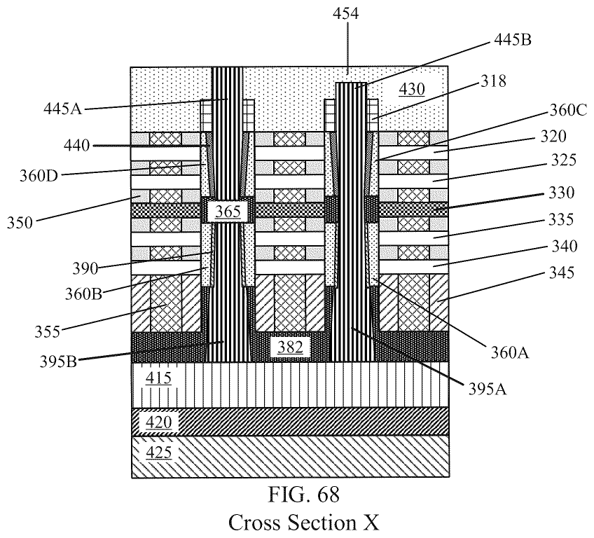

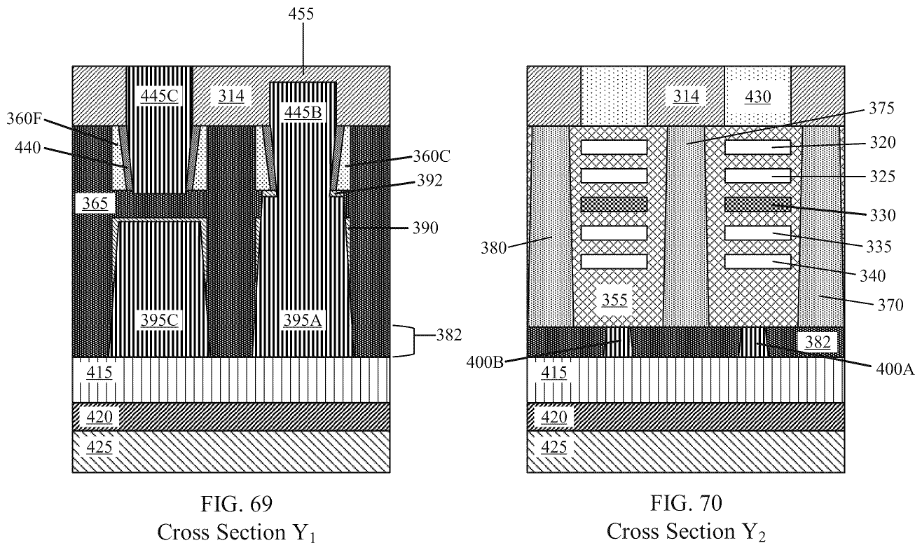

FIGS. 68-70 illustrate cross sections X, Y₁, and Y₂, respectively, of the plurality of nanodevices ND1, ND2 after the formation of the isolation ILD 454, an isolation STI material 455, and CMP, in accordance with the embodiment of the present invention. The second lithography mask layer 450 is removed. The isolation ILD 454 may be a backside isolation ILD. In FIG. 68, a different dielectric material is deposited in the eighth trench 452 (FIG. 65) to form the isolation ILD 454. The isolation ILD 454 is located directly atop the second source/drain contact 445B and may be comprised of a same material as the BILD layer 430. A portion of the isolation ILD 454 is removed by, for example, CMP. In FIG. 69, a same material as the STI region 314 is deposited in the eighth trench 452 (FIG. 66) to form the isolation STI material 455. A portion of the isolation STI material 455 is removed by, for example, CMP.

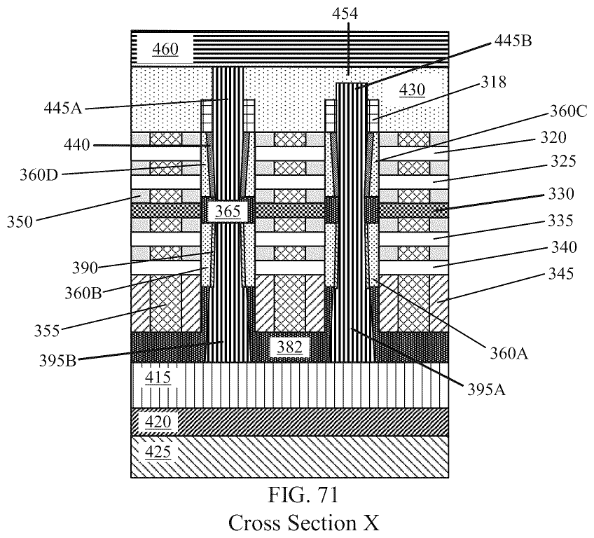

FIGS. 71-73 illustrate cross sections X, Y₁, and Y₂, respectively, of the plurality of nanodevices ND1, ND2 after the formation of the backside interconnect 460, in accordance with the embodiment of the present invention. The isolation ILD 454 includes the backside isolation ILD in direct contact with a backside surface of the shared source/drain contact 395A, 445B. The backside interconnect 460 is in direct contact with a backside surface of the backside isolation ILD 454, a backside surface of the first independent backside source/drain contact 445A, and a backside surface of the second independent backside source/drain contact 445C.

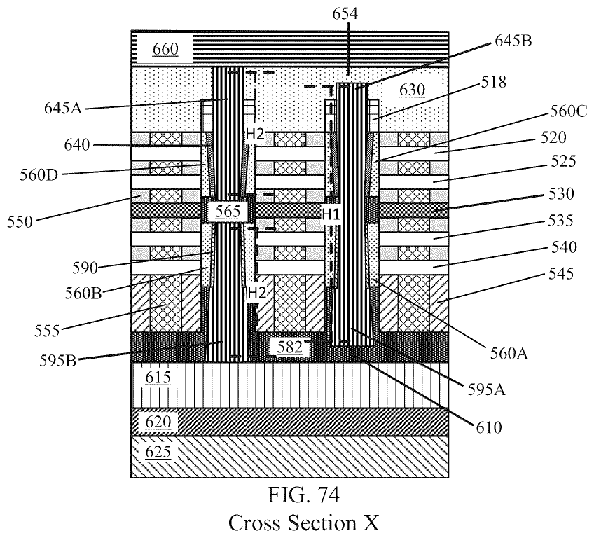

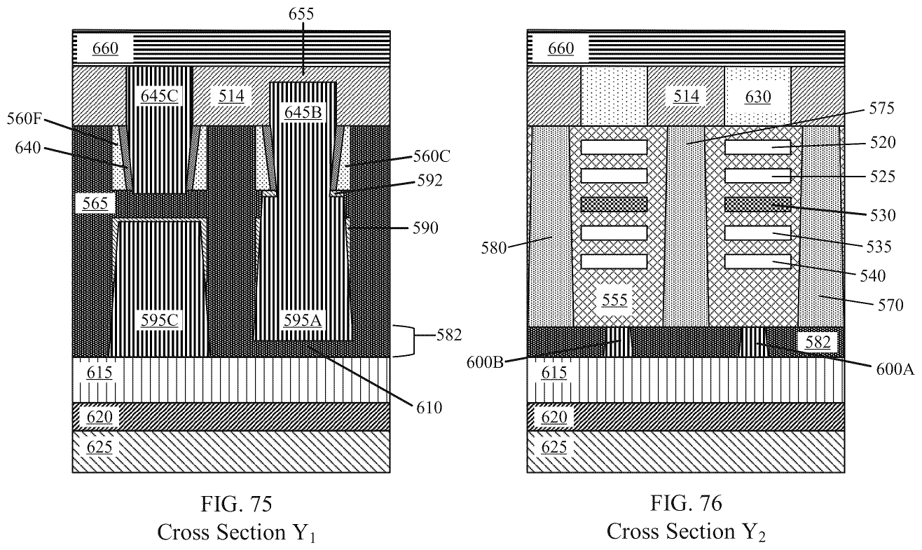

FIGS. 74-76 illustrate cross sections X, Y₁, and Y₂, respectively, of the plurality of nanodevices ND1, ND2 after ILD 565 deposition and additional ILD 582 deposition, nanosheet 520, 525, 535, 540 formation, STI region 514 formation, gate 555 formation, gate spacer 545 and inner spacer 550 formation, MDI layer 530 formation, source/drain 560A, 560B, 560C, 560D, 560F formation, source/drain contact 595A, 595B, 595C, 645A, 645B, 645C formation, gate contact 600A, 600B formation, protective liner 518 formation, gate cut dielectric pillar 570, 575, 580 formation, first frontside silicide liner 590 formation, backside silicide liner 640 formation, BEOL layer 615 formation, bonding oxide layer 620 formation, carrier wafer 625 bonding, BILD layer 630 formation, isolation ILD 610, 654 formation, STI isolation material 655 formation, and backside interconnect 660 formation, in accordance with the embodiment of the present invention.

The isolation ILD 610, 654 includes a frontside isolation ILD 610 in direct contact with a frontside surface of the shared source/drain contact 595A, 645B and a backside isolation ILD 654 in direct contact with a backside surface of the shared source/drain contact 595A, 645B.

The BEOL layer 615 is in direct contact with a frontside surface of the frontside isolation ILD 610, a frontside surface of the first independent source/drain contact 595B, and a frontside surface of the second independent source/drain contact 595C. The backside interconnect 660 is in direct contact with a backside surface of the backside isolation ILD 654, a backside surface of the first independent backside source/drain contact 645A, and backside surface of the second independent backside source/drain contact 645C. The shared source/drain contact 595A, 645B extends a first height H1 perpendicular to a y-axis. The first independent source/drain contact 595B and the first independent backside source/drain contact 645A each extend a second height H2 perpendicular to the y-axis. The first height H1 is greater than the second height H2.

The shared source/drain contact 195A, 245B extends through the first upper source/drain 160A and the first lower source/drain 160C. The isolation ILD 210 includes the frontside isolation ILD 210 in direct contact with the frontside surface of the shared source/drain contact 195A, 245B. The BEOL layer 215 is in direct contact with the frontside surface of the frontside isolation ILD 210.

The shared source/drain contact 395A, 445B extends through the first upper source/drain 360A and the first lower source/drain 360C. The isolation ILD 454 includes the backside isolation ILD 454 in direct contact with the backside surface of the shared source/drain contact 395A, 445B. The backside interconnect 460 is in direct contact with the backside surface of the backside isolation ILD 454.

The shared source/drain contact 595A, 645B extends through the first upper source/drain 560A and the first lower source/drain 560C. The isolation ILD 610, 654 includes the frontside isolation ILD 610 in direct contact with the frontside surface of the shared source/drain contact 595A, 645B and the backside isolation ILD 654 in direct contact with the backside surface of the shared source/drain contact 595A, 645B. The BEOL layer 615 is in direct contact with the frontside surface of the frontside isolation ILD 610. The backside interconnect 660 is in direct contact with the backside surface of the backside isolation ILD 654.

It may be appreciated that FIGS. 1-76 provide only an illustration of one implementation and do not imply any limitations with regard to how different embodiments may be implemented. Many modifications to the depicted environments may be made based on design and implementation requirements.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a first nanodevice including a plurality of first upper transistors and a plurality of first lower transistors, wherein the first nanodevice includes a first upper source/drain and a first lower source/drain;
a shared source/drain contact extending through the first upper source/drain and the first lower source/drain; and
an isolation interlayer dielectric (ILD) in direct contact with at least one surface of the shared source/drain contact.

2. The semiconductor device of claim 1, wherein the isolation ILD includes a frontside isolation ILD in direct contact with a frontside surface of the shared source/drain contact.

3. The semiconductor device of claim 2, further comprising:
a back-end-of-line (BEOL) layer in direct contact with a frontside surface of the frontside isolation ILD.

4. The semiconductor device of claim 1, wherein the isolation ILD includes a backside isolation ILD in direct contact with a backside surface of the shared source/drain contact.

5. The semiconductor device of claim 4, further comprising:
a backside interconnect in direct contact with a backside surface of the backside isolation ILD.

6. The semiconductor device of claim 1, wherein the isolation ILD includes a frontside isolation ILD in direct contact with a frontside surface of the shared source/drain contact and a backside isolation ILD in direct contact with a backside surface of the shared source/drain contact.

7. The semiconductor device of claim 6, further comprising:
a BEOL layer in direct contact with a frontside surface of the frontside isolation ILD; and
a backside interconnect in direct contact with a backside surface of the backside isolation ILD.

8. A semiconductor device comprising:
a first nanodevice including a plurality of first upper transistors and a plurality of first lower transistors, wherein the first nanodevice includes a first upper source/drain, a second upper source/drain, a first lower source/drain, and a second lower source/drain;
a shared source/drain contact extending through the first upper source/drain and the first lower source/drain;
a first independent source/drain contact extending upwards through the second upper source/drain and a first independent backside source/drain contact extending downwards through the second lower source/drain; and
an isolation ILD in direct contact with at least one surface of the shared source/drain contact.

9. The semiconductor device of claim 8, wherein the isolation ILD includes a frontside isolation ILD in direct contact with a frontside surface of the shared source/drain contact.

10. The semiconductor device of claim 9, further comprising:
a BEOL layer in direct contact with a frontside surface of the frontside isolation ILD and a frontside surface of the first independent source/drain contact.

11. The semiconductor device of claim 8, wherein the isolation ILD includes a backside isolation ILD in direct contact with a backside surface of the shared source/drain contact.

12. The semiconductor device of claim 11, further comprising:
a backside interconnect in direct contact with a backside surface of the backside isolation ILD and a backside surface of the first independent backside source/drain contact.

13. The semiconductor device of claim 8, wherein the isolation ILD includes a frontside isolation ILD in direct contact with a frontside surface of the shared source/drain contact and a backside isolation ILD in direct contact with a backside surface of the shared source/drain contact.

14. The semiconductor device of claim 13, further comprising:
a BEOL layer in direct contact with a frontside surface of the frontside isolation ILD and a frontside surface of the first independent source/drain contact; and
a backside interconnect in direct contact with a backside surface of the backside isolation ILD and a backside surface of the first independent backside source/drain contact.

15. A semiconductor device comprising:
a first nanodevice including a plurality of first upper transistors and a plurality of first lower transistors, wherein the first nanodevice includes a first upper source/drain, a second upper source/drain, a first lower source/drain, and a second lower source/drain;
a second nanodevice including a plurality of second upper transistors and a plurality of second lower transistors, wherein the second nanodevice is located adjacent to and parallel to the first nanodevice, wherein the second nanodevice includes a third upper source/drain and a third lower source/drain;
a shared source/drain contact extending through the first upper source/drain and the first lower source/drain;
a first independent source/drain contact extending upwards through the second upper source/drain, a second independent source/drain contact extending upwards through the third upper source/drain, a first independent backside source/drain contact extending downwards through the second lower source/drain, and a second independent backside source/drain contact extending downwards through the third lower source/drain; and
an isolation ILD in direct contact with at least one surface of the shared source/drain contact.

16. The semiconductor device of claim 15, wherein the isolation ILD includes a frontside isolation ILD in direct contact with a frontside surface of the shared source/drain contact, wherein the semiconductor device further comprises:
a BEOL layer in direct contact with a frontside surface of the frontside isolation ILD, a frontside surface of the first independent source/drain contact, and a frontside surface of the second independent source/drain contact.

17. The semiconductor device of claim 15, wherein the isolation ILD includes a backside isolation ILD in direct contact with a backside surface of the shared source/drain contact, wherein the semiconductor device further comprises:
a backside interconnect in direct contact with a backside surface of the backside isolation ILD, a backside surface of the first independent backside source/drain contact, and a backside surface of the second independent backside source/drain contact.

18. The semiconductor device of claim 15, wherein the isolation ILD includes a frontside isolation ILD in direct contact with a frontside surface of the shared source/drain contact and a backside isolation ILD in direct contact with a backside surface of the shared source/drain contact, wherein the semiconductor device further comprises:
a BEOL layer in direct contact with a frontside surface of the frontside isolation ILD, a frontside surface of the first independent source/drain contact, and a frontside surface of the second independent source/drain contact; and
a backside interconnect in direct contact with a backside surface of the backside isolation ILD, a backside surface of the first independent backside source/drain contact, and a backside surface of the second independent backside source/drain contact.

19. The semiconductor device of claim 15, wherein the shared source/drain contact extends a first height perpendicular to a y-axis, wherein the first independent source/drain contact and the first independent backside source/drain contact each extend a second height perpendicular to the y-axis, and wherein the first height is greater than the second height.

20. The semiconductor device of claim 19, further comprising:
a frontside silicide liner located along a first portion of sidewalls of the shared source/drain contact where the shared source/drain contact passes through the first upper source/drain; and
a backside silicide liner located along a second portion of the sidewalls of the shared source/drain contact where the shared source/drain contact passes through the first lower source/drain, wherein the frontside silicide liner and the backside silicide liner are comprised of a different material.
